(19) United States
(12) Patent Application Publication
(10) Pub. No.: US 2009/0296959 A1
(43) Pub. Date: Dec. 3, 2009

(54) MISMATCHED SPEAKER SYSTEMS AND METHODS

(75) Inventor: Anthony BONGIOVI, Port St. Lucie, FL (US)

Correspondence Address: DON J. PELTO;Sheppard, Mullin, Richter & Hampton LLP, 1300 I STREET, NW, 11TH FLOOR EAST, WASHINGTON, DC, 20005, US

(73) Assignee: Bongiovi Acoustics, LLC, Port St. Lucie, FL (US)

(21) Appl. No.: 12/474,050

(22) Filed: May 28, 2009

Related U.S. Application Data
(63) Continuation-in-part of application No. 11/947,301, filed on Nov. 29, 2007.
Application No. 11/947,301 is a continuation-in-part of application No. 11/703,216, filed on Feb. 7, 2007.
(60) Provisional application No. 60/861,711, filed on Nov. 30, 2006.
(60) Provisional application No. 60/765,722, filed on Feb. 7, 2006.

(51) Int. Cl. H03G 5/00

(52) U.S. Cl. 381/103; 381/98

(57) ABSTRACT

According to various embodiments, an audio system having high quality sound and a high frequency response is provided. The audio system comprises one or more speakers with mismatched components. Although the combination of mismatched components may result in a diminished frequency response, digital signal processing may compensate for the physical deficiencies of a driver of the speaker. In some embodiments, an audio system comprises a speaker and a signal processor. The speaker may comprise one or more mismatched speaker components which are operably coupled to each other such that the components, together, have a low frequency response. The signal processor may operably couple to the one or more mismatched speaker components. The signal processor may be configured to process an input signal and to drive the speaker using the processed signal such that the speaker has a higher frequency response than the low frequency response.

### CROSS REFERENCE TO RELATED APPLICATIONS

The present application is a continuation-in-part of U.S. application Ser. No. 11/947,301, filed June Nov. 29, 2007, which claims priority to U.S. Provisional Application No. 60/861,711 filed Nov. 30, 2006, and is a continuation-in-part of U.S. application Ser. No. 11/703,216, filed Feb. 7, 2007, which claims priority to U.S. Provisional Application No. 60/765,722, filed Feb. 7, 2006, all of which are incorporated fully herein by reference. The present application also claims the benefit, under 35 U.S.C. § 119, of provisional U.S. Application Ser. No. 61/057,726, filed May 30, 2008, which is also hereby incorporated fully herein by reference.

### FIELD OF THE INVENTION

The present invention relates an acoustic speaker system and method. More particularly, the present invention relates to a mismatched speakers and methods.

### BACKGROUND OF THE INVENTION

Historically, studio-quality sound, which can best be described as the full reproduction of the complete range of audio frequencies that are utilized during the studio recording process, has only been able to be achieved, appropriately, in audio recording studios. Studio-quality sound is characterized by the level of clarity and brightness which is attained only when the upper-mid frequency ranges are effectively manipulated and reproduced. While the technical underpinnings of studio-quality sound can be fully appreciated only by experienced record producers, the average listener can easily hear the difference that studio-quality sound makes.

While various attempts have been made to reproduce studio-quality sound outside of the recording studio, those attempts have come at tremendous expense (usually resulting from advanced speaker design, costly hardware, and increased power amplification) and have achieved only mixed results. Thus, there exists a need for a process whereby studio-quality sound can be reproduced outside of the studio with consistent, high quality, results at a low cost. There exists a further need for audio devices embodying such a process, as well as computer chips embodying such a process that may be embedded within audio devices. There also exists a need for the ability to produce studio-quality sound through inexpensive speakers.

In cellular telephones, little has been done to enhance and optimize the audio quality of the voice during a conversation or of audio programming during playback. Manufacturers have, in some cases, attempted to enhance the audio, but generally this is accomplished utilizing the volume control of the device. The general clarity of the voice ‘sound’ remains fixed. The voice is merely amplified and/or equalized. Moreover, the settings for amplification and/or equalization are also fixed and cannot be altered by the user.

Further, the design of audio systems for vehicles involves the consideration of many different factors. The audio system designer selects the position and number of speakers in the vehicle. The desired frequency response of each speaker must also be determined. For example, the desired frequency response of a speaker that is located on the instrument panel may be different than the desired frequency response of a speaker that is located on the lower portion of the rear door panel.

The audio system designer must also consider how equipment variations impact the audio system. For example, an audio system in a convertible may not sound as good as the same audio system in the same model vehicle that is a hard top. The audio system options for the vehicle may also vary significantly. One audio option for the vehicle may include a basic 4-speaker system with 40 watts amplification per channel while another audio option may include a 12-speaker system with 200 watts amplification per channel. The audio system designer must consider all of these configurations when designing the audio system for the vehicle. For these reasons, the design of audio systems is time consuming and costly. The audio system designers must also have a relatively extensive background in signal processing and equalization.

Given those considerations, in order to achieve something approaching studio-quality sound in a vehicle historically one would have required a considerable outlay of money, including expensive upgrades of the factory-installed speakers. As such, there is a need for a system that can reproduce studio-quality sound in a vehicle without having to make such expensive outlays.

The presentation of quality sound in moving motor vehicles is particularly challenging due to the high noise environment therein. This is compounded by the fact that speakers in vehicles, as well as speakers in any closed or small volume areas, are often placed in less than ideal positions. As a result of poor speaker location, sound produced by speakers may bounce off various surfaces before reaching the listeners.

One solution to this problem is to place speakers in the headliner of the motor vehicle, thus allowing the sound to reach the occupants of the vehicle unimpeded. Another solution is to use high quality speakers or speakers having high (good) and broad frequency responses. However, high quality speakers with good and broad frequency response can be very expensive and/or weighty.

### SUMMARY OF THE INVENTION

The present invention meets the existing needs described above by providing for a method of digitally processing an audio signal in a manner such that studio-quality sound that can be reproduced across the entire spectrum of audio devices. The present invention also provides for a computer chip that can digitally processing an audio signal is such a manner, and provides for audio devices that comprise such a chip.

The present invention further meets the above stated needs by allowing inexpensive speakers to be used in the reproduction of studio-quality sound. Furthermore, the present invention meets the existing needs described above by providing for a mobile audio device that can be used in a vehicle to reproduce studio-quality sound using the vehicle's existing speaker system by digitally manipulating audio signals. Indeed, even the vehicle's factory-installed speakers can be used to achieve studio-quality sound using the present invention.

In one embodiment, the present invention provides for a method comprising the steps of inputting an audio signal, adjusting the gain of that audio signal a first time, processing that signal with a first low shelf filter, processing that signal with a first high shelf filter, processing that signal with a first compressor, processing that signal with a second low shelf filter, processing that signal with a second high shelf filter, processing that signal with a graphic equalizer, processing that signal with a second compressor, and adjusting the gain of that audio signal a second time. In this embodiment, the audio signal is manipulated such that studio-quality sound is produced. Further, this embodiment compensates for any inherent volume differences that may exist between audio sources or program material, and produces a constant output level of rich, full sound.

This embodiment also allows the studio-quality sound to be reproduced in high-noise environments, such as moving automobiles. Some embodiments of the present invention allow studio-quality sound to be reproduced in any environment. This includes environments that are well designed with respect to acoustics, such as, without limitation, a concert hall. This also includes environments that are poorly designed with respect to acoustics, such as, without limitation, a traditional living room, the interior of vehicles and the like. Further, some embodiments of the present invention allow the reproduction of studio-quality sound irrespective of the quality of the electronic components and speakers used in association with the present invention. Thus, the present invention can be used to reproduce studio-quality sound with both top-of-the-line and bottom-of-the-line electronics and speakers, and with everything in between.

In some embodiments, this embodiment may be used for playing music, movies, or video games in high-noise environments such as, without limitation, an automobile, airplane, boat, club, theatre, amusement park, or shopping center. Furthermore, in some embodiments, the present invention seeks to improve sound presentation by processing an audio signal outside the efficiency range of both the human ear and audio transducers which is between approximately 600 Hz and approximately 1,000 Hz. By processing audio outside this range, a fuller and broader presentation may be obtained.

In some embodiments, the bass portion of the audio signal may be reduced before compression and enhanced after compression, thus ensuring that the sound presented to the speakers has a spectrum rich in bass tones and free of the muffling effects encountered with conventional compression. Furthermore, in some embodiments, as the dynamic range of the audio signal has been reduced by compression, the resulting output may be presented within a limited volume range. For example, the present invention may comfortably present studio-quality sound in a high-noise environment with an 80 dB noise floor and a 110 dB sound threshold.

In some embodiments, the method specified above may be combined with over digital signal processing methods that are perform before the above-recited method, after the above-recited method, or intermittently with the above-recited method.

In another specific embodiment, the present invention provides for a computer chip that may perform the method specified above. In one embodiment, the computer chip may be a digital signal processor, or DSP. In other embodiments, the computer chip may be any processor capable of performing the above-stated method, such as, without limitation, a computer, computer software, an electrical circuit, an electrical chip programmed to perform these steps, or any other means to perform the method described.

In another embodiment, the present invention provides for an audio device that comprises such a computer chip. The audio device may comprise, for example and without limitation: a radio; a CD player; a tape player; an MP3 player; a cell phone; a television; a computer; a public address system; a game station such as a Playstation 3 (Sony Corporation—Tokyo, Japan), an X-Box 360 (Microsoft Corporation—Redmond, Wash.), or a Nintendo Wii (Nintendo Co., Ltd.—Kyoto, Japan); a home theater system; a DVD player; a video cassette player; or a Blu-Ray player.

In such an embodiment, the chip of the present invention may be delivered the audio signal after it passes through the source selector and before it reaches the volume control. Specifically, in some embodiments the chip of the present invention, located in the audio device, processes audio signals from one or more sources including, without limitation, radios, CD players, tape players, DVD players, and the like. The output of the chip of the present invention may drive other signal processing modules or speakers, in which case signal amplification is often employed.

Specifically, in one embodiment, the present invention provides for a mobile audio device that comprises such a computer chip. Such a mobile audio device may be placed in an automobile, and may comprise, for example and without limitation, a radio, a CD player, a tape player, an MP3 player, a DVD player, or a video cassette player.

In this embodiment, the mobile audio device of the present invention may be specifically tuned to each vehicle it may be used in to obtain optimum performance and to account for unique acoustic properties in each vehicle such as speaker placement, passenger compartment design, and background noise. Also in this embodiment, the mobile audio device of the present invention may provide precision tuning for all 4 independently controlled channels. Also in this embodiment, the mobile audio device of the present invention may deliver about 200 watts of power. Also in this embodiment, the mobile audio device of the present invention may use the vehicle's existing (sometimes factory-installed) speaker system to produce studio-quality sound. Also in this embodiment, the mobile audio device of the present invention may comprise a USB port to allow songs in standard digital formats to be played. Also in this embodiment, the mobile audio device of the present invention may comprise an adapter for use with satellite radio. Also in this embodiment, the mobile audio device of the present invention may comprise an adaptor for use with existing digital audio playback devices such as, without limitation, MP3 players. Also in this embodiment, the mobile audio device of the present invention may comprise a remote control. Also in this embodiment, the mobile audio device of the present invention may comprise a detachable faceplate.

In various embodiments, a method comprises receiving a profile comprising a plurality of filter equalizing coefficients, configuring a plurality of filters of a graphic equalizer with the plurality of filter equalizing coefficients from the profile, receiving a first signal for processing, adjusting the plurality of filters using a first gain, equalizing the first signal using the plurality of filters of the graphic equalizer, outputting the first signal, receiving a second signal for processing, adjusting the plurality of filters, previously configured with the filter equalizing coefficients from the profile, using a second gain, equalizing the second plurality of frequencies of the second signal with the plurality of filters of the graphic equalizer, and outputting the second signal. The profile may be received from a communication network and/or from firmware.

The plurality of filters may be configured using the plurality of filter equalizing coefficients to modify the first signal to clarify a sound of a voice during a telephone communication, to modify the first signal to clarify a sound of a voice in a high noise environment, and/or to modify the first signal to adjust a sound associated with a media file for a handheld device.

Prior to equalizing the first signal, the method may further comprise adjusting a gain of the first signal, filtering the adjusted first signal with a low shelf filter, and compressing the filtered first signal with a compressor. Further, the method may comprise, after equalizing the first signal, compressing the equalized first signal with a compressor, and adjusting the gain of the compressed first signal.

In some embodiments, the method further comprises filtering the first signal with a first low filter, filtering the first signal received from the first low shelf filter with a first high shelf filter prior to compressing the filtered signal with a compressor, filtering the first signal with a second low shelf filter prior to equalizing the first signal with the graphic equalizer, and filtering the first signal with a second high shelf filter after the first signal is filtered with the second low shelf filter.

The plurality of filters of the graphic equalizer may comprise eleven cascading second order filters. Each of the second order filters may be bell filters.

In some embodiments, a system comprises a graphic equalizer. The graphic equalizer may comprise a filter module, a profile module, and an equalizing module. The filter module comprises a plurality of filters. The profile module may be configured to receive a profile comprising a plurality of filter equalizing coefficients. The equalizing module may be configured to configure the plurality of filters with the plurality of filter equalizing coefficients from the profile, to receive first and second signals, to adjust the plurality of filters using a first gain, to equalize the first plurality using the plurality of filters of the graphic equalizer, to output the first signal, to adjust the plurality of filters, previously configured with the filter equalizing coefficients from the profile, using a second gain, to equalize the second signal using the plurality of filters of the graphic equalizer, and to output the second signal.

In various embodiments, a method comprises configuring a graphic equalizer with a plurality of filter equalizing coefficients, adjusting the graphic equalizer using a first gain, processing the first signal with the graphic equalizer, outputting the first signal from the graphic equalizer, adjusting the graphic equalizer using a second gain, processing the second signal with the graphic equalizer, the graphic equalizer being previously configured with the plurality of filter equalizing coefficients, and outputting the second signal from the graphic equalizer.

In some embodiments, a computer readable medium may comprise executable instructions. The instructions may be executable by a processor for performing a method. The method may comprise receiving a profile comprising a plurality of filter equalizing coefficients, configuring a plurality of filters of a graphic equalizer using the plurality of filter equalizing coefficients from the profile, receiving a first signal for processing, adjusting the plurality of filters using a first gain, equalizing the first signal using the plurality of filters of the graphic equalizer, outputting the first signal, receiving a second signal for processing, adjusting the plurality of filters, previously configured using the filter coefficients from the profile, using a second gain, equalizing the second plurality of frequencies of the second signal with the plurality of filters of the graphic equalizer, and outputting the second signal.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

According to various embodiments, an audio system having high quality sound and a high frequency response is provided. The audio system comprises one or more speakers with mismatched components. Although the combination of mismatched components may result in a diminished frequency response, digital signal processing may compensate for the physical deficiencies of a driver of the speaker. The digital signal processing may manipulate and condition the source program signals and result in high quality sound and a high frequency response.

In some embodiments, an audio system comprises a speaker and a signal processor. The speaker may comprise one or more mismatched speaker components which are operably coupled to each other such that the components, together, have a low frequency response. The signal processor may operably couple to the one or more mismatched speaker components. The signal processor may be configured to process an input signal and to drive the speaker using the processed signal such that the speaker has a higher frequency response than the low frequency response.

The mismatched components may comprise a voice coil and a magnet, wherein the voice coil may be oversized in relation to a size of a magnet of the speaker. The signal processor may be further configured to prevent the larger voice coil from overdriving the magnet. The magnet may be a rare earth magnet. The cone may comprise organize fibers. In some embodiments, the cone is dampened which contributes to the low frequency response.

In some embodiments, the signal processor may further comprise a first filter, a gain controller, a second filter, an equalizer, and an output. The first filter may be configured to filter a signal to obtain a generally flat power spectral density. The gain controller may be configured to alter a dynamic range of the signal by reducing the ratio between a signal's peak level and a signal's average level. The second filter may be configured to convert the signal to a full frequency response. The equalizer may be configured to equalize the signal. The output may be configured to output the signal to the speaker.

The equalizer may comprise a 10 band parametric equalizer. The first and the second filter may each comprise a high and low shelving filter combination set. The signal processor may further comprise a pre-input high pass filter configured to filter a signal received by the audio system. Further, the signal processor may further comprise a leaky integrator configured to gain adjust the signal by computing a loudness level of the signal.

In various embodiments, there is method to process a signal to compensate for a speaker comprising mismatched components. The method may comprise receiving a signal, filtering a signal to obtain a generally flat power spectral density, altering a dynamic range of the signal by reducing the ratio between a signal's peak level and a signal's average level, converting the signal to a full frequency response, and equalizing the signal, and outputting the signal to a speaker with one or more mismatched components. The method may further comprising receiving a selection of an audio play back device; and calibrating the equalizer based on the selection.

Further, the method may comprise filtering the signal to limit low frequencies and gain adjusting the signal by computing a loudness level of the signal. Gain adjusting may further comprise increasing a gain of the signal based on the loudness level. Alternately, gain adjusting may further comprises decreasing a gain of the signal based on the loudness level.

In some embodiments, the method further comprises configuring a signal processor to compensate for a low frequency response produced by mismatched components of a speaker. Further, the method may further comprise gain adjusting the signal, after filtering the signal, to modify the gain level of the signal.

The method may also comprise loudness adjusting to compensate for loudness variations. The method may comprise compressing the signal after filtering a signal to obtain a generally flat power spectral density. The signal may also be compressed after equalizing.

In various embodiments, a computer readable medium comprises instructions. The instructions may be executable by a processor for performing a method to process a signal to compensate for a speaker comprising mismatched components. The method may comprise receiving a signal, filtering a signal to obtain a generally flat power spectral density, altering a dynamic range of the signal by reducing the ratio between a signal's peak level and a signal's average level, converting the signal to a full frequency response, equalizing the signal, and outputting the signal to a speaker with one or more mismatched components.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

FIG. 1 shows a block diagram of one embodiment of the digital signal processing method of the present invention.

FIG. 2 shows the effect of a low-shelf filter used in one embodiment of the digital signal processing method of the present invention.

FIG. 3 shows how a low-shelf filter can be created using high-pass and low-pass filters.

FIG. 4 shows the effect of a high-shelf filter used in one embodiment of the digital signal processing method of the present invention.

FIG. 5 shows the frequency response of a bell filter used in one embodiment of the digital signal processing method of the present invention.

FIG. 6 shows a block diagram of one embodiment of a graphic equalizer used in one embodiment of the digital signal processing method of the present invention.

FIG. 7 shows a block diagram showing how a filter can be constructed using the Mitra-Regalia realization.

FIG. 8 shows the effect of magnitude-complementary low-shelf filters that may be used in one embodiment of the digital signal processing method of the present invention.

FIG. 9 shows a block diagram of an implementation of a magnitude-complementary low-shelf filter that may be used in one embodiment of the digital signal processing method of the present invention.

FIG. 10 shows the static transfer characteristic (the relationship between output and input levels) of a compressor used in one embodiment of the digital signal processing method of the present invention.

FIG. 11 shows a block diagram of a direct form type 1 implementation of second order transfer function used in one embodiment of the digital signal processing method of the present invention.

FIG. 12 shows a block diagram of a direct form type 1 implementation of second order transfer function used in one embodiment of the digital signal processing method of the present invention.

FIG. 13 is an illustration of an exemplary speaker.

FIG. 14 is an illustration of an exemplary audio system including a speaker with mismatched components and a DSP coupled with the speaker.

FIG. 15 is an illustration of a flow chart of an exemplary audio processing method implemented by the DSP.

FIG. 16 is an illustration of an exemplary process flow of a portion of step 1510.

FIG. 17 is an illustration of an exemplary digital signal process.

FIG. 18 is an illustration of an exemplary computer module in which a computer processing method may be implemented.

The figures are not intended to be exhaustive or to limit the invention to the precise form disclosed. It should be understood that the invention can be practiced with modification and alteration, and that the invention be limited only by the claims and the equivalents thereof.

### DETAILED DESCRIPTION

According to various embodiments, an audio system having high quality sound and a high frequency response is provided. The audio system comprises one or more speakers with mismatched components. Although the combination of mismatched components may result in a diminished frequency response, digital signal processing may compensate for the physical deficiencies of a driver of the speaker. The digital signal processing may manipulate and condition the source program signals and result in high quality sound and a high frequency response.

Mismatched components may comprise inexpensive and/or lightweight material. In one example, mismatched components may comprise an underrated magnet and basket mass when compared to conventional loudspeaker designs. The speaker with an underrated component may have a lighter driver with poor frequency response as well as other deficient physical specifications. The driver may also comprise mismatched and large windings in the speaker driver engine to overcome power handling requirements. The mismatched and large windings may also degrade the signal response of the speaker.

In some embodiments, by using mismatched components and digital signal processing, a speaker may weigh less than a speaker with matched components yet produce a high frequency response. The lighter speaker may not only provide a discount in the actual manufacturing costs of the speaker and system but could be used to help to increase a Corporate Average Fuel Economy (CAFE) rating by decreasing the total weight of the vehicle and, hence, increasing the miles per gallon of the vehicle using this lighter speaker system. This design may also generate smaller amounts of waste when the driver has reached its end of useful life by using fewer raw materials in the initial design. The use of fewer raw materials may provide for a “greener” product for the end consumer and the environment.

Moreover, in high fidelity designs, audio driver motors of specific size and material composition allow for quality reproduction of sound. However, under-rating the mass of the magnet will normally deteriorate the frequency response of the speaker. Furthermore, the use of certain non-traditional materials in the overall construction of the speaker—such as plastics, composites, glues, and papers—are also known to deteriorate the frequency response.

The ability to construct speakers that, while maintaining quality performance, are more lightweight and are composed of alternative materials may have a variety of benefits. For instance, to be able to use plastics or composites in place of certain raw materials may lower production costs, and may likewise serve as an environmentally-friendly alternative, given the ravishing of lands and the pollution associated with the processing necessary for such raw materials.

In addition, scaling the size of the speakers alone may also result in lower production costs. Related to the scaling of the size of components is the resulting reduction of mass. Choosing to manufacture speakers that are smaller and more lightweight may be environmentally friendly in multiple facets. The speaker's magnets alone could be made of iron-ferrite, neodymium, strontium, or barium. As a result, decreasing the overall size of the speaker would generate less waste of such metals when the speaker disposed. Moreover, all other components of a smaller speaker—including the basket, voice coils, cone, spider, etc.—may likewise correspond to less waste production when disposed. In addition, for applications in automobiles, the lower mass of the speakers would improve the overall fuel efficiency for the vehicle, thus helping automotive manufacturers achieve a better CAFE rating.

Some embodiments may allow one or more of these financial and environmental benefits to be realized, by incorporating the use of DSP technology, as well as component sizing and other techniques, to compensate for the normal, poor frequency performance that may be a result of alternative materials and smaller components.

It is to be understood that the present invention is not limited to the particular methodology, compounds, materials, manufacturing techniques, uses, and applications described herein, as these may vary. It is also to be understood that the terminology used herein is used for the purpose of describing particular embodiments only, and is not intended to limit the scope of the present invention. It must be noted that as used herein and in the appended embodiments, the singular forms “a,” “an,” and “the” include the plural reference unless the context clearly dictates otherwise. Thus, for example, a reference to “an audio device” is a reference to one or more audio devices and includes equivalents thereof known to those skilled in the art. Similarly, for another example, a reference to “a step” or “a means” is a reference to one or more steps or means and may include sub-steps and subservient means. All conjunctions used are to be understood in the most inclusive sense possible. Thus, the word “or” should be understood as having the definition of a logical “or” rather than that of a logical “exclusive or” unless the context clearly necessitates otherwise. Language that may be construed to express approximation should be so understood unless the context clearly dictates otherwise.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention. Structures described herein are to be understood also to refer to functional equivalents of such structures.

First, some background on linear time-invariant systems is helpful. A linear, time-invariant (LTI) discrete-time filter of order N with input x[k] and output y[k] is described by the following difference equation:

y[k]=b₀x[k]+b₁x[k−1]+ . . . +b_{N}x[k−N]+a₁y[k−1]+a₂y[k−2]+ . . . +a_{N}y[k−N]

where the coefficients {b0, b1, . . . , bN, a1, a2, . . . , aN} are chosen so that the filter has the desired characteristics (where the term desired can refer to time-domain behavior or frequency domain behavior).

The difference equation above can be excited by an impulse function, δ[k], whose value is given by

$$δ [ k ] = \{ \begin{matrix}1 , & k = 0 \\ 0 , & k \neq 0\end{matrix}$$

When the signal δ[k] is applied to the system described by the above difference equation, the result is known as the impulse response, h[k]. It is a well-known result from system theory that the impulse response h[k] alone completely characterizes the behavior of a LTI discrete-time system for any input signal. That is, if h[k] is known, the output y[k] for an input signal x[k] can be obtained by an operation known as convolution. Formally, given h[k] and x[k], the response y[k] can be computed as

$$y [ k ] = {\sum }_{n = 0}^{∞} h [ n ] x [ k - n ]$$

Some background on the z-transform is also helpful. The relationship between the time-domain and the frequency-domain is given by a formula known as the z-transform. The z-transform of a system described by the impulse response h[k] can be defined as the function H(z) where

$$H ( z ) = {\sum }_{k = 0}^{∞} h [ k ] {z}^{- k}$$

and z is a complex variable with both real and imaginary parts. If the complex variable is restricted to the unit circle in the complex plane (i.e., the region described by the relationship |z|=1), what results is a complex variable that can be described in radial form as

z=e^{jθ}, where 0≦θ2π and j=\sqrt{−1}

Some background on the discrete-time fourier transform is also instructive. With z described in radial form, the restriction of the z-transform to the unit circle is known as the discrete-time Fourier transform (DTFT) and is given by

$$H ( {e}^{jθ} ) = {\sum }_{k = 0}^{∞} h [ k ] {e}^{- j k θ}$$

Of particular interest is how the system behaves when it is excited by a sinusoid of a given frequency. One of the most significant results from the theory of LTI systems is that sinusoids are eigenfunctions of such systems. This means that the steady-state response of an LTI system to a sinusoid sin(θ0 k) is also a sinusoid of the same frequency θ 0, differing from the input only in amplitude and phase. In fact, the steady-state output, yss[k] of the LTI system when driven by and input x[k]=sin(θ0 k) is given by

yₐₛ[k]=A sin(θ₀k+φ₀)

where

A=|H(e^{j0}^{₀})|

and

φ₀=arg(H(e^{jθ}^{₀}))

Finally, some background on frequency response is needed. The equations above are significant because indicate that the steady-state response of an LTI system when driven by a sinusoid is a sinusoid of the same frequency, scaled by the magnitude of the DTFT at that frequency and offset in time by the phase of the DTFT at that frequency. For the purposes of the present invention, what is of concern is the amplitude of the steady state response, and that the DTFT provides us with the relative magnitude of output-to-input when the LTI system is driven by a sinusoid. Because it is well-known that any input signal may be expressed as a linear combination of sinusoids (the Fourier decomposition theorem), the DTFT can give the response for arbitrary input signals. Qualitatively, the DTFT shows how the system responds to a range of input frequencies, with the plot of the magnitude of the DTFT giving a meaningful measure of how much signal of a given frequency will appear at the system's output. For this reason, the DTFT is commonly known as the system's frequency response.

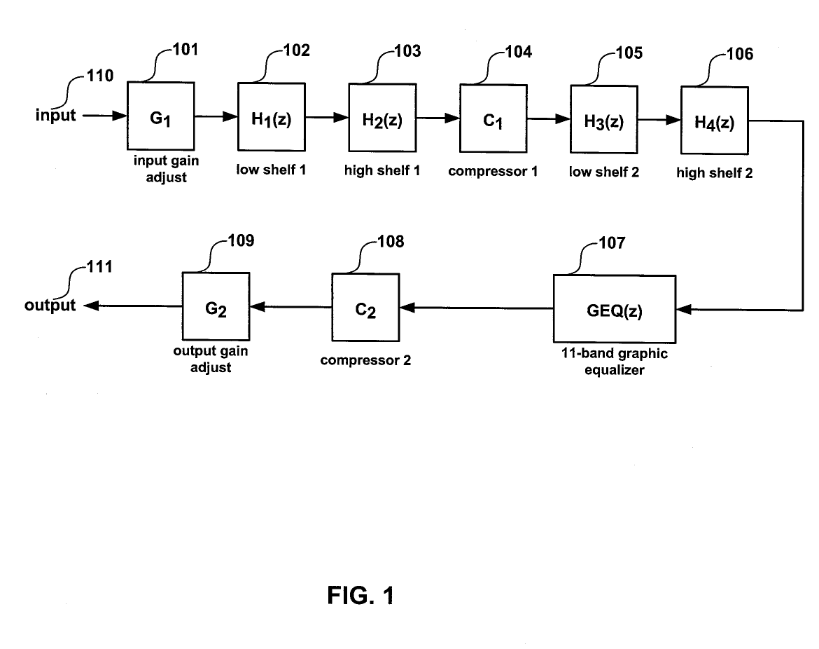

FIG. 1 illustrates an example digital signal process flow of a method 100 according to one embodiment of the present invention. Referring now to FIG. 1, method 100 includes the following steps: input gain adjustment 101, first low shelf filter 102, first high shelf filter 103, first compressor 104, second low shelf filter 105, second high shelf filter 106, graphic equalizer 107, second compressor 108, and output gain adjustment 109.

In one embodiment, digital signal processing method 100 may take as input audio signal 110, perform steps 101-109, and provide output audio signal 111 as output. In one embodiment, digital signal processing method 100 is executable on a computer chip, such as, without limitation, a digital signal processor, or DSP. In one embodiment, such a chip may be one part of a larger audio device, such as, without limitation, a radio, MP3 player, game station, cell phone, television, computer, or public address system. In one such embodiment, digital signal processing method 100 may be performed on the audio signal before it is outputted from the audio device. In one such embodiment, digital signal processing method 100 may be performed on the audio signal after it has passed through the source selector, but before it passes through the volume control.

In one embodiment, steps 101-109 may be completed in numerical order, though they may be completed in any other order. In one embodiment, steps 101-109 may exclusively be performed, though in other embodiments, other steps may be performed as well. In one embodiment, each of steps 101-109 may be performed, though in other embodiments, one or more of the steps may be skipped.

In one embodiment, input gain adjustment 101 provides a desired amount of gain in order to bring input audio signal 110 to a level that will prevent digital overflow at subsequent internal points in digital signal processing method 100.

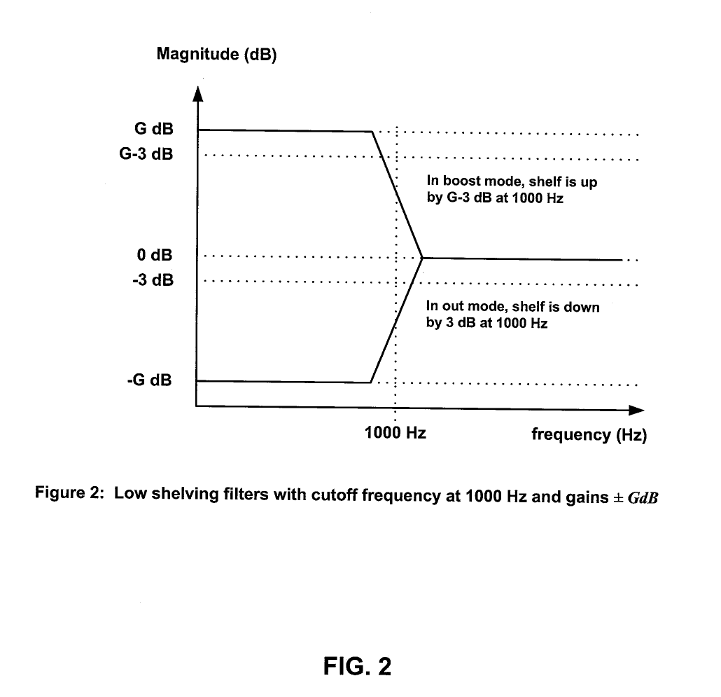

In one embodiment, each of the low-shelf filters 102, 105 is a filter that has a nominal gain of 0 dB for all frequencies above a certain frequency termed the corner frequency. For frequencies below the corner frequency, the low-shelving filter has a gain of ±G dB, depending on whether the low-shelving filter is in boost or cut mode, respectively. This is shown in FIG. 2.

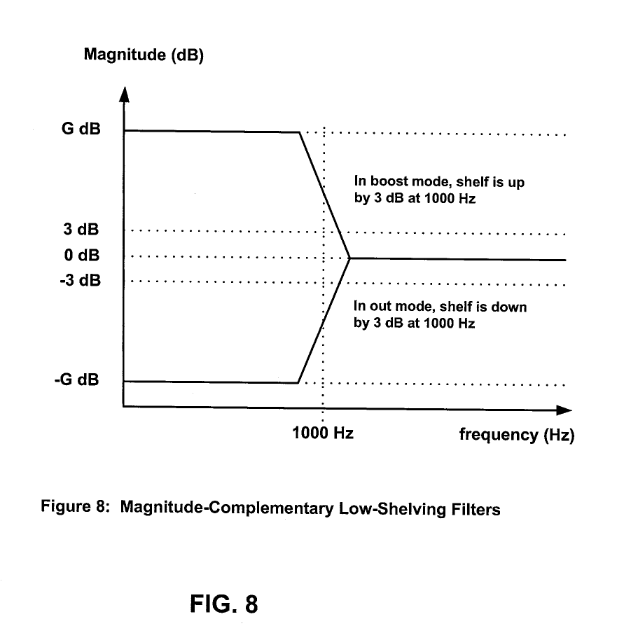

FIG. 2 illustrates the effect of a low-shelf filter being implemented by one embodiment of the present invention. Referring now to FIG. 8, the purpose of a low-shelving filter is to leave all of the frequencies above the corner frequency unaltered, while boosting or cutting all frequencies below the corner frequency by a fixed amount, G dB. Also note that the 0 dB point is slightly higher than the desired 1000 Hz. It is standard to specify a low-shelving filter in cut mode to have a response that is at −3 dB at the corner frequency, whereas a low-shelving filter in boost mode is specified such that the response at the corner frequency is at G−3 dB —namely, 3 dB down from maximum boost. Indeed, all of the textbook formulae for creating shelving filters lead to such responses. This leads to a certain amount of asymmetry, where for almost all values of boost or cut G, the cut and boost low-shelving filters are not the mirror images of one another. This is something that needed to be address by the present invention, and required an innovative approach to the filters' implementations.

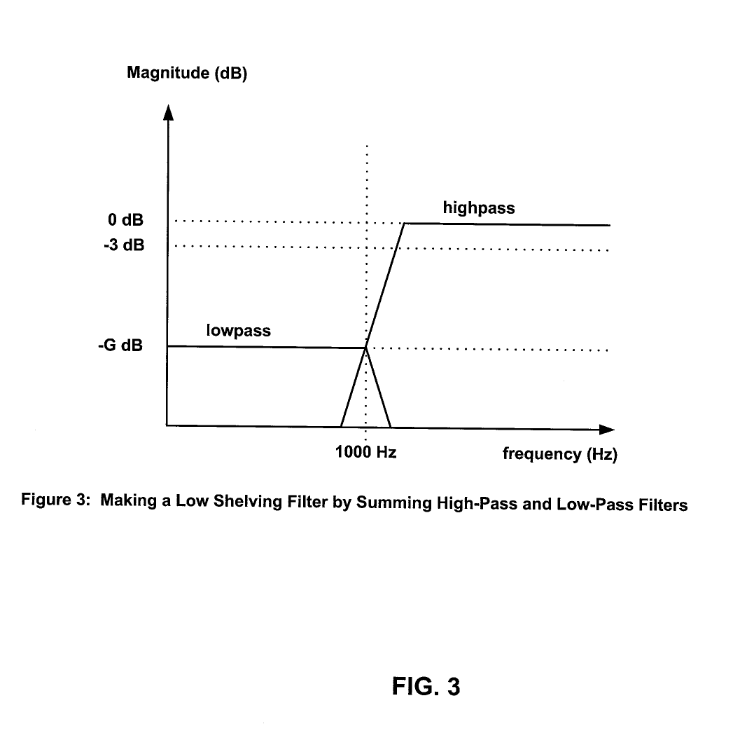

Ignoring for now the asymmetry, the standard method for creating a low-shelving filter is as the weighted sum of highpass and lowpass filters. For example, let's consider the case of a low-shelving filter in cut mode with a gain of −G dB and a corner frequency of 1000 Hz. FIG. 3 shows a highpass filter with a 1000 cutoff frequency and a lowpass filter with a cutoff frequency of 1000 Hz, scaled by −G dB. The aggregate effect of these two filters applied in series looks like the low-shelving filter in FIG. 2. In practice, there are some limitations on the steepness of the transition from no boost or cut to G dB of boost or cut. FIG. 3 illustrates this limitation, with the corner frequency shown at 1000 Hz and the desired G dB of boost or cut not being achieved until a particular frequency below 1000 Hz. It should be noted that all of the shelving filters in the present invention are first-order shelving filters, which means they can usually be represented by a first-order rational transfer function:

$$H ( z ) = \frac{{b}_{0} + {b}_{1} {z}^{- 1}}{1 + {a}_{1} {z}^{- 1}} .$$

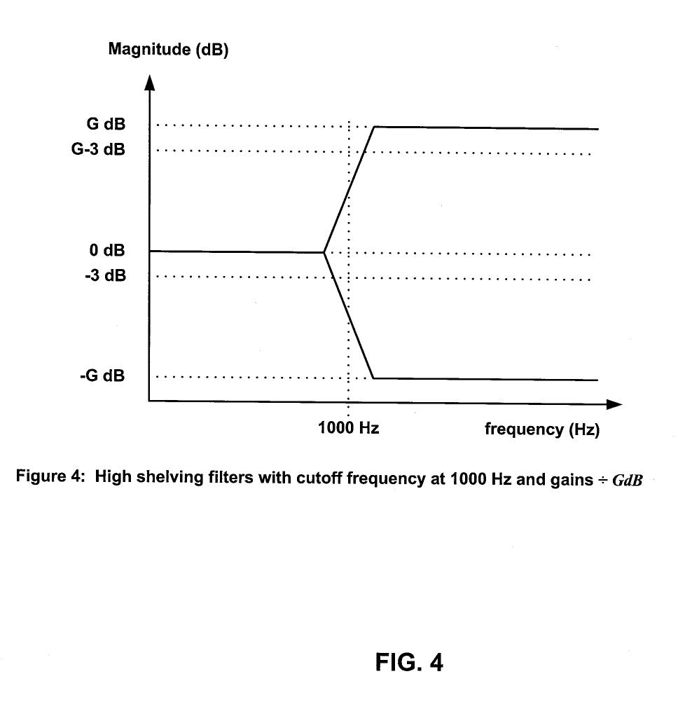

In some embodiments, each of the high-shelf filters 103, 106 is nothing more than the mirror image of a low-shelving filter. That is, all frequencies below the corner frequency are left unmodified, whereas the frequencies above the corner frequency are boosted or cut by G dB. The same caveats regarding steepness and asymmetry apply to the high-shelving filter. FIG. 4 illustrates the effect of a high-shelf filter implemented by an embodiment of the present invention. Referring now to FIG. 4, a 1000 Hz high-shelving filter is shown.

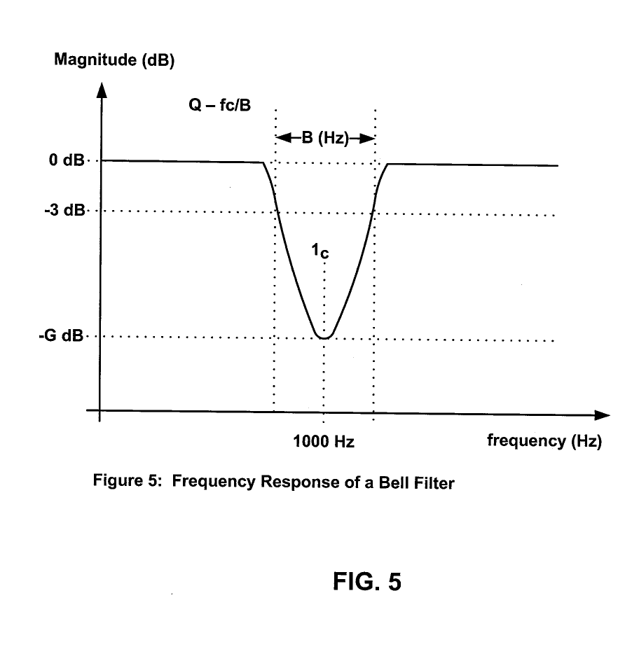

FIG. 5 illustrates an example frequency response of a bell filter implemented by method 100 according to one embodiment of the present invention. As shown in FIG. 5, each of the second order filters achieves a bell-shaped boost or cut at a fixed center frequency, with F1(z) centered at 30 Hz, F11(z) centered at 16000 Hz, and the other filters in between centered at roughly one-octave intervals. Referring to FIG. 5, a bell-shaped filter is shown centered at 1000 Hz. The filter has a nominal gain of 0 dB for frequencies above and below the center frequency, 1000 Hz, a gain of −G dB at 1000 Hz, and a bell-shaped response in the region around 1000 Hz.

The shape of the filter is characterized by a single parameter: the quality factor, Q. The quality factor is defined as the ratio of the filter's center frequency to its 3-dB bandwidth, B, where the 3-dB bandwidth is illustrated as in the figure: the difference in Hz between the two frequencies at which the filter's response crosses the −3 dB point.

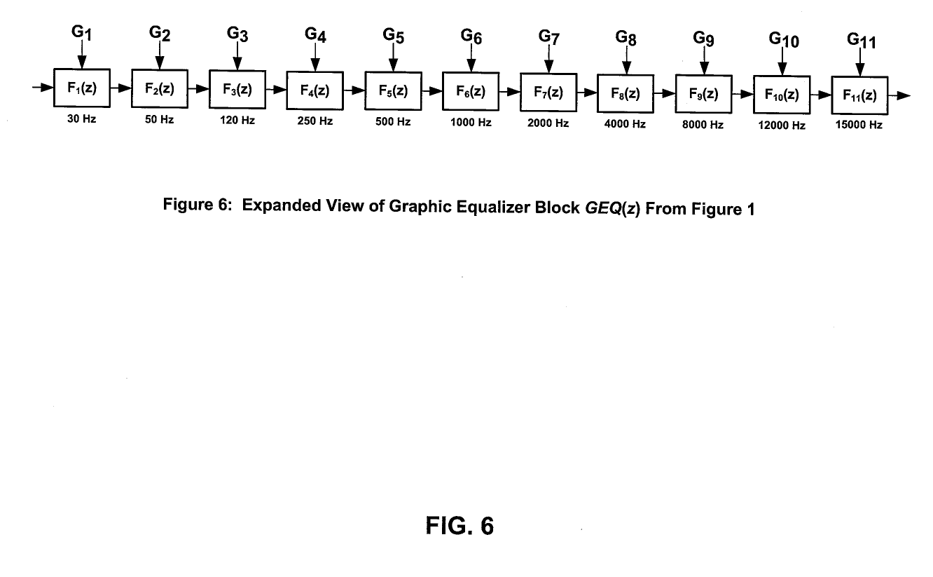

FIG. 6 illustrates an example graphic equalizer block 600 according to one embodiment of the present invention. Referring now to FIG. 6, graphic equalizer 600 consists of a cascaded bank of eleven second-order filters, F₁(z), F₂(z), . . . , F₁₁(z). In one embodiment, graphic equalizer 107 (as shown in FIG. 1) is implemented as graphic equalizer 600.

Each of the eleven second-order filters in the present invention can be computed from formulas that resemble this one:

$$F ( z ) = \frac{{b}_{0} + {b}_{1} {z}^{- 1} + {b}_{2} {z}^{- 2}}{1 + {a}_{1} {z}^{- 1} + {a}_{2} {z}^{- 2}} .$$

Using such an equation results in one problem: each of the five coefficients above, {b₀, b₁, b₂, a₁, a₂} depends directly on the quality factor, Q, and the gain, G. This means that for the filter to be tunable, that is, to have variable Q and G, all five coefficients must be recomputed in real-time. This can be problematic, as such calculations could easily consume the memory available to perform graphic equalizer 107 and create problems of excessive delay or fault, which is unacceptable. This problem can be avoided by utilizing the Mitra-Regalia Realization.

A very important result from the theory of digital signal processing (DSP) is used to implement the filters used in digital signal processing method 100. This result states that a wide variety of filters (particularly the ones used in digital signal processing method 100) can be decomposed as the weighted sum of an allpass filter and a feedforward branch from the input. The importance of this result will become clear. For the time being, suppose that a second-order transfer function, H(z), is being implements to describes a bell filter centered at fc with quality factor Q and sampling frequency Fs by

$$H ( z ) = \frac{{b}_{0} + {b}_{1} {z}^{- 1} + {b}_{2} {z}^{- 2}}{1 + {a}_{1} {z}^{- 1} + {a}_{2} {z}^{- 2}}$$

Ancillary quantities k1, k2 can be defined by

$${k}_{1} = \frac{1 - tan ( \frac{π {f}_{c}}{{QF}_{s}} )}{1 + tan ( \frac{π {f}_{c}}{{QF}_{s}} )}$$

$${k}_{2} = cos ( \frac{2 π {f}_{c}}{{F}_{s}} )$$

and transfer function, A(z) can be defined by

$$A ( z ) = \frac{{k}_{2} + {k}_{1} ( 1 + {k}_{2} ) {z}^{- 1} + {z}^{- 2}}{1 + {k}_{1} ( 1 + {k}_{2} ) {z}^{- 1} + {k}_{2} {z}^{- 2}}$$

A(z) can be verified to be an allpass filter. This means that the amplitude of A(z) is constant for all frequencies, with only the phase changing as a function of frequency. A(z) can be used as a building block for each bell-shaped filter. The following very important result can be shown:

$$H ( z ) = \frac{1}{2} ( 1 + G ) A ( z ) + \frac{1}{2} ( 1 - G )$$

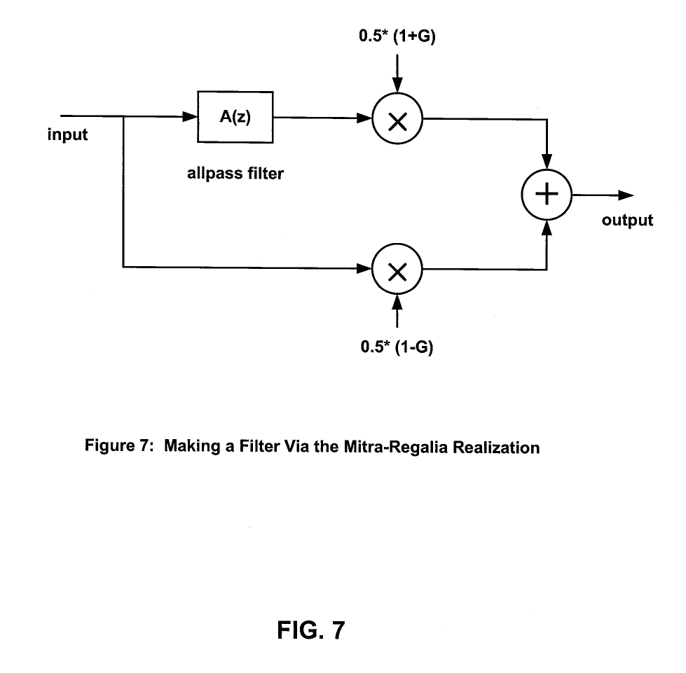

This is the crux of the Mitra-Regalia realization. A bell filter with tunable gain can be implemented to show the inclusion of the gain G in a very explicit way. This is illustrated in FIG. 7, which illustrates an example filter constructed using the Mitra-Regalia realization according to one embodiment of the present invention.

There is a very good reason for decomposing the filter in such a non-intuitive manner. Referring to the above equation, remember that every one of the a and b coefficients needs to be re-computed whenever G gets changed (i.e., whenever one of the graphic EQ “slider” is moved). Although the calculations that need to be performed for the a and b coefficients have not been shown, they are very complex and time-consuming and it simply isn't practical to recompute them in real time. However, in a typical graphic EQ, the gain G and quality factor Q remain constant and only G is allowed to vary. This is what makes the equation immediately above so appealing. Notice from the above equations that A(z) does not depend in any way on the gain, G and that if Q and the center-frequency fc remain fixed (as they do in a graphic EQ filter), then k1 and k2 remain fixed regardless of G. Thus, these variables only need to be computed once! Computing the gain variable is accomplished by varying a couple of simple quantities in real time:

$$\frac{1}{2} ( 1 + G )$$

$$and$$

$$\frac{1}{2} ( 1 - G ) .$$

These are very simple computations and only require a couple of CPU cycles. This leaves only the question of how to implement the allpass transfer function, A(z), which is a somewhat trivial exercise. The entire graphic equalizer bank thus consists of 11 cascaded bell filters, each of which is implemented via its own Mitra-Regalia realization:

$${F}_{1} ( z ) fixed {k}_{1}^{1} , {k}_{2}^{1} , variable {G}_{1}$$

$${F}_{1} ( z ) fixed {k}_{1}^{2} , {k}_{2}^{2} , variable {G}_{2}$$

$$⋮ ⋮$$

$${F}_{11} ( z ) fixed {k}_{1}^{11} , {k}_{2}^{11} , variable {G}_{11}$$

It can be seen from that equation that the entire graphic equalizer bank depends on a total of 22 fixed coefficients that need to be calculated only once and stored in memory. The “tuning” of the graphic equalizer is accomplished by adjusting the parameters G1, G2, . . . , G11. Refer back to FIG. 6 to see this in schematic form. The Mitra-Regalia realization will be used over and over in the implementation of the various filters used digital signal processing method 100. Mitra-Regalia is also useful in implementing the shelving filters, where it is even simpler because the shelving filters use first-order filter. The net result is that a shelving filter is characterized by a single allpass parameter, k, and a gain, G. As with the bell filters, the shelving filters are at fixed corner frequencies (in fact, all of them have 1 kHz as their corner frequency) and the bandwidth is also fixed. All told, four shelving filters are completely described simply by
H₁(z)→fixed k¹, G₁
H₂(z)→fixed k², G₂
H₃(z)→fixed k³, G₃
H₄(z)→fixed k⁴, G₄

As discussed above, there is an asymmetry in the response of a conventional shelving filter when the filter is boosting versus when it is cutting. This is due, as discussed, to the design technique having different definitions for the 3-dB point when boosting than when cutting. Digital signal processing method 100 relies on the filters H1(z) and H3(z) being the mirror images of one another and the same holds for H2(z) and H4(z). This led to the use of a special filter structure for the boosting shelving filters, one that leads to perfect magnitude cancellation for H1, H3 and H2, H4, as shown in FIG. 8. This type of frequency response is known as magnitude complementary. This structure is unique to the present invention. In general, it is a simple mathematical exercise to derive for any filter H(z) a filter with complementary magnitude response. The filter H−1 (z) certainly fits the bill, but may not be stable or implementable function of z, in which case the solution is merely a mathematical curiosity and is useless in practice. This is the case with a conventional shelving filter. The equations above show how to make a bell filter from an allpass filter. These equation applies equally well to constructing a shelving filter beginning with a first-order allpass filter, A(z), where

$$A ( z ) = \frac{α - {z}^{- 1}}{1 - α {z}^{- 1}}$$

and α is chosen such that

$$α = \frac{( 1 - sin ( \frac{2 π {f}_{c}}{{F}_{s}} ) )}{cos ( \frac{2 π {f}_{c}}{{F}_{s}} )}$$

where fc is the desired corner frequency and Fs is the sampling frequency. Applying the above equations and re-arranging terms, this can be expressed as

$$H ( z ) = \frac{1 + G}{2} \{ 1 + \frac{1 - G}{1 + G} A ( z ) \} .$$

This is the equation for a low-shelving filter. (A high-shelving filter can be obtained by changing the term (1−G) to (G−1)). Taking the inverse of H(z) results in the following:

$$\frac{1}{H ( z )} = \frac{2}{( 1 + G ) ( 1 + \frac{1 - G}{1 + G} A ( z ) )} .$$

This equation is problematic because it contains a delay-free loop, which means that it can not be implemented via conventional state-variable methods. Fortunately, there are some recent results from system theory that show how to implement rational functions with delay-free loops. Fontana and Karjalainen show that each step can be “split” in time into two “sub-steps.”

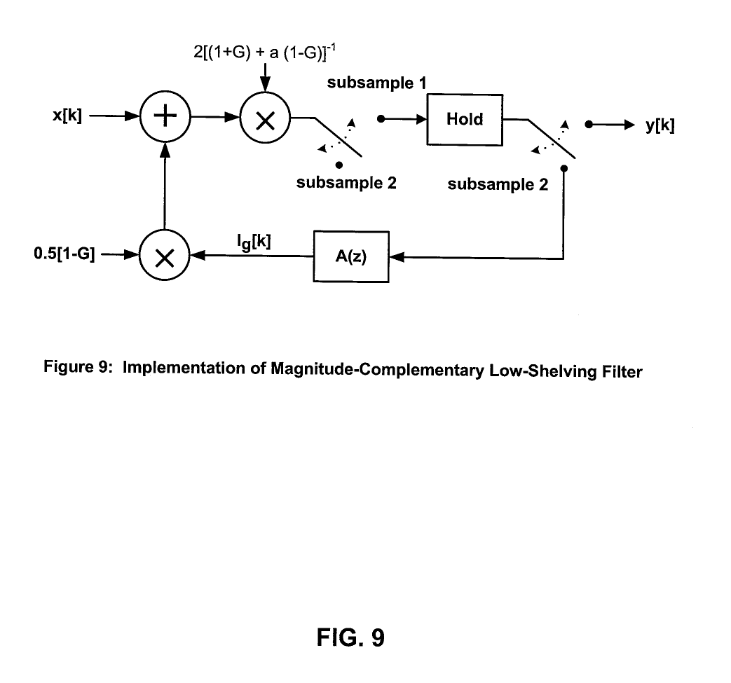

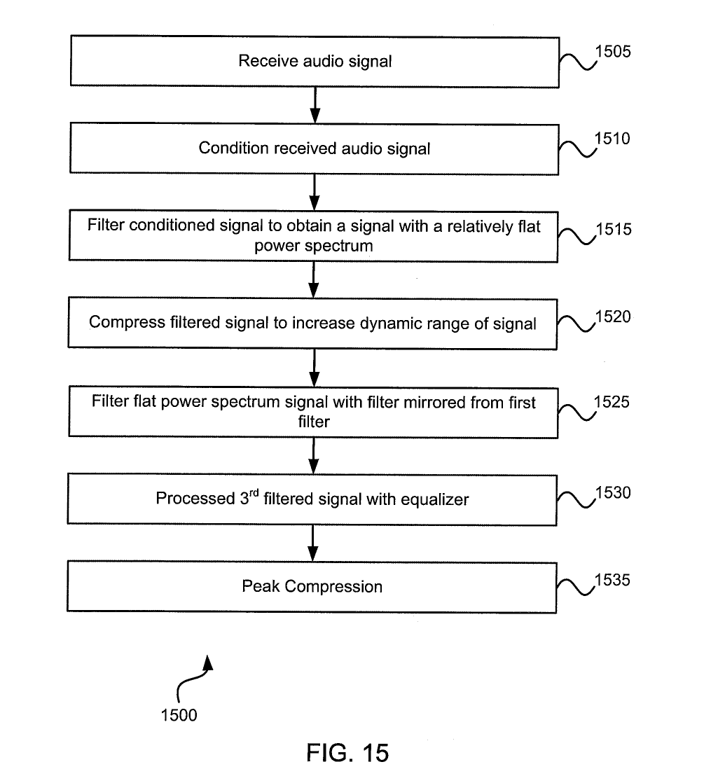

FIG. 9 illustrates an example magnitude-complementary low-shelf filter according to one embodiment of the present invention. Refer to FIG. 15, during the first sub-step (labeled “subsample 1”), feed filter A(z) with zero input and compute its output, 10[k]. During this same subsample, calculate the output y[k] using the value of 10[k], which from the equation immediately above can be performed as follows:

$$\begin{matrix}y [ k ] = \frac{1}{1 + α \frac{1 - G}{1 + G}} \{ \frac{2}{1 + G} x [ k ] + \frac{1 - G}{1 + G} {l}_{0} [ k ] \} \\ = \frac{2}{( 1 + G ) + α ( 1 - G )} \{ x [ k ] + \frac{1 - G}{2} {l}_{0} [ k ] \}\end{matrix}$$

It can be seen from FIG. 9 that these two calculations correspond to the case where the switches are in the “subsample 1” position. Next, the switches are thrown to the “subsample 2” position and the only thing left to do is update the internal state of the filter A(z). This unconventional filter structure results in perfect magnitude complementarity, 11. This can be exploited for the present invention in the following manner: when the shelving filters of digital signal processing method 100 are in “cut” mode, the following equation can be used:

$$H ( z ) = \frac{1 + G}{2} \{ 1 + \frac{1 - G}{1 + G} A ( z ) \} .$$

However, when the shelving filters of digital signal processing method 100 are in “boost” mode, the following equation can be used with the same value of G as used in “cut” mode:

$$\begin{matrix}y [ k ] = \frac{1}{1 + α \frac{1 - G}{1 + G}} \{ \frac{2}{1 + G} x [ k ] + \frac{1 - G}{1 + G} {l}_{0} [ k ] \} \\ = \frac{2}{( 1 + G ) + α ( 1 - G )} \{ x [ k ] + \frac{1 - G}{2} {l}_{0} [ k ] \}\end{matrix}$$

This results in shelving filters that are perfect mirror images of on another, as per FIG. 8, which is what is needed for digital signal processing method 100. (Note: Equation 16 can be changed to make a high-shelving filter by changing the sign on the (1−G)/2 term). FIG. 8 illustrates the effect of a magnitude-complementary low-shelf filter implemented by an embodiment of the present invention.

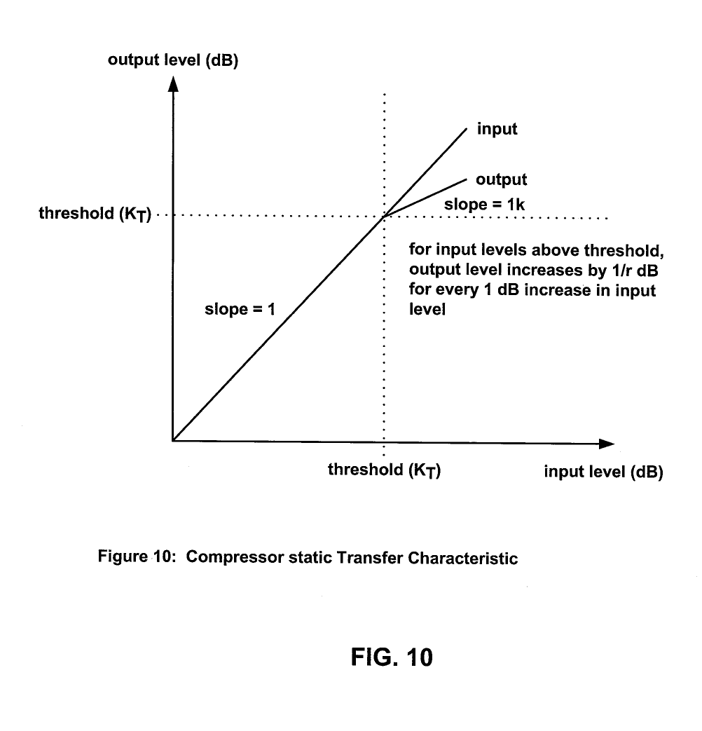

Each of the compressors 104, 108 is a dynamic range compressor designed to alter the dynamic range of a signal by reducing the ratio between the signal's peak level and its average level. A compressor is characterized by four quantities: the attack time, Tatt, the release time, Trel, the threshold, KT, and the ratio, r. In brief, the envelope of the signal is tracked by an algorithm that gives a rough “outline” of the signal's level. Once that level surpasses the threshold, KT, for a period of time equal to Tatt, the compressor decreases the level of the signal by the ratio r dB for every dB above KT. Once the envelope of the signal falls below KT for a period equal to the release time, Trel, the compressor stops decreasing the level. FIG. 10 illustrates a static transfer characteristic (relationship between output and input levels) of a compressor implemented in accordance to one embodiment of the present invention.

It is instructive to examine closely the static transfer characteristic. Assume that the signal's level, L[k] at instant k has been somehow computed. For instructive purposes, a one single static level, L, will be considered. If L is below the compressor's trigger threshold, KT, the compressor does nothing and allows the signal through unchanged. If, however, L is greater than KT, the compressor attenuates the input signal by r dB for every dB by which the level L exceeds KT.

It is instructive to consider an instance where L is greater than KT, which means that 20 log₁₀(L)>20 log₁₀(KT). In such an instance, the excess gain, i.e., the amount in dB by which the level exceeds the threshold, is: g_{excess}=20 log₁₀(L)−20 log₁₀(KT). As the compressor attenuates the input by r dB for every dB of excess gain, the gain reduction, gR, can be expressed as

$${g}_{R} = \frac{{g}_{excess}}{R} = \frac{1}{R} \cdot ( 20 {log}_{10} ( L ) - 20 {log}_{10} ( {K}_{T} ) )$$

From that, it follows that that with the output of the compressor, y given by 20 log₁₀(y)=gR*20 log₁₀(x), that the desired output-to-input relationship is satisfied.

Conversion of this equation to the linear, as opposed to the logarithmic, domain yields the following:

$$y = {( {10}^{{log}_{10} ( x )} )}^{\frac{1}{R} \cdot ( {log}_{10} ( L ) - {log}_{10} ( {K}_{T} ) )}$$

Which is equivalent to:

$$y = {x}^{\frac{1}{R} \cdot ( {log}_{10} ( L ) - {log}_{10} ( {K}_{T} ) )} = {x}^{\frac{1}{R} \cdot ( {log}_{10} ( L / {K}_{T} ) )}$$

The most important part of the compressor algorithm is determining a meaningful estimate of the signal's level. This is accomplished in a fairly straightforward way: a running “integration” of the signal's absolute value is kept, where the rate at which the level is integrated is determined by the desired attack time. When the instantaneous level of the signal drops below the present integrated level, the integrated level is allowed to drop at a rate determined by the release time. Given attack and release times Tatt and Trel, the equation used to keep track of the level, L[k] is given by

$$L [ k ] = \{ \begin{matrix}( 1 - {α}_{att} ) \vert x [ k ] \vert + {α}_{att} L [ k - 1 ] & for \vert x [ k ] \vert \geq L [ k - 1 ] \\ ( 1 - {α}_{rel} ) \vert x [ k ] \vert + {α}_{rel} L [ k - 1 ] & for \vert x [ k ] \vert < L [ k - 1 ]\end{matrix} \\ where \\ {α}_{att} = exp ( \frac{1}{{F}_{s} {T}_{att}} ) \\ and \\ {α}_{rel} = exp ( \frac{1}{5 {F}_{s} {T}_{rel}} )$$

At every point of the level calculation as described above, L[k] as computed is compared to the threshold KT, and if L[k] is greater than KT, the input signal, x[k], is scaled by an amount that is proportional to the amount by which the level exceeds the threshold. The constant of proportionality is equal to the compressor ratio, r. After a great deal of mathematical manipulation, the following relationship between the input and the output of the compressor is established:

With the level L[k] as computed in Equation 18, the quantity Gexcess by is computed as

G_{excess}=L[k]K_{T}⁻¹,

which represents the amount of excess gain. If the excess gain is less than one, the input signal is not changed and passed through to the output. In the event that the excess gain exceeds one, the gain reduction, GR is computed by:

$${G}_{R} = {( {G}_{excess} )}^{\frac{1 - r}{r}} = {( L [ k ] {K}_{T}^{- 1} )}^{\frac{1 - r}{r}}$$

and then the input signal is scaled by GR and sent to the output:

output[k]=G_{R}x[k].

Through this procedure, an output signal whose level increases by 1/r dB for every 1 dB increase in the input signal's level is created.

In practice, computing the inverse K_{T}⁻¹ for the above equations can be time consuming, as certain computer chips are very bad at division in real-time. As KT is known in advance and it only changes when the user changes it, a pre-computed table of K_{T}⁻¹ values can be stored in memory and used as needed. Similarly, the exponentiation operation in the above equation calculating GR is extremely difficult to perform in real time, so pre-computed values can be used as an approximation. Since quantity GR is only of concern when Gexcess is greater than unity, a list of, say, 100 values of GR, pre-computed at integer values of GR from GR=1 to GR=100 can be created for every possible value of ratio r. For non-integer values of GR (almost all of them), the quantity in the above equation calculating GR can be approximated in the following way. Let interp be the amount by which Gexcess exceeds the nearest integral value of Gexcess. In other words,

interp=G_{excess}−└(G_{excess})┘

and let GR,0 and GR,1 refer to the pre-computed values

$${G}_{R , 0} = {⌊ ( {G}_{excess} ) ⌋}^{\frac{1 - r}{r}}$$

$$and$$

$${G}_{R , 1} = {⌊ ( 1 + {G}_{excess} ) ⌋}^{\frac{1 - r}{r}} .$$

Linear interpolation may then be used to compute an approximation of GR as follows:

G_{R}≈_{R,0}+interp*(G_{R,1}−G_{R,0})

The error between the true value of GR and the approximation in the above equation can be shown to be insignificant for the purposes of the present invention. Furthermore, the computation of the approximate value of GR requires only a few arithmetic cycles and several reads from pre-computed tables. In one embodiment, tables for six different values of ratio, r, and for 100 integral points of Gexcess may be stored in memory. In such an embodiment, the entire memory usage is only 600 words of memory, which can be much more palatable than the many hundred cycles of computation that would be necessary to calculate the true value of GR directly. This is a major advantage of the present invention.

Each of the digital filters in digital signal processing method 100 may be implemented using any one a variety of potential architectures or realizations, each of which has its trade-offs in terms of complexity, speed of throughput, coefficient sensitivity, stability, fixed point behavior, and other numerical considerations. In a specific embodiment, a simple architecture known as a direct-form architecture of type 1 (DF1) may be used. The DF1 architecture has a number of desirable properties, not the least of which is its clear correspondence to the difference equation and the transfer function of the filter in question. All of the digital filters in digital signal processing method 100 are of either first or second order.

The second-order filter will be examined in detail first. As discussed above, the transfer function implemented in the second-order filter is given by

$$H ( z ) = \frac{{b}_{0} + {b}_{1} {z}^{- 1} + {b}_{2} {z}^{- 2}}{1 + {a}_{1} {z}^{- 1} + {a}_{2} {z}^{- 2}} ,$$

which corresponds to the difference equation

y[k]=b₀x[k]+b₁x[k−1]+b₂x[k−2]−a₁y[k−1]−a₂y[k−2].

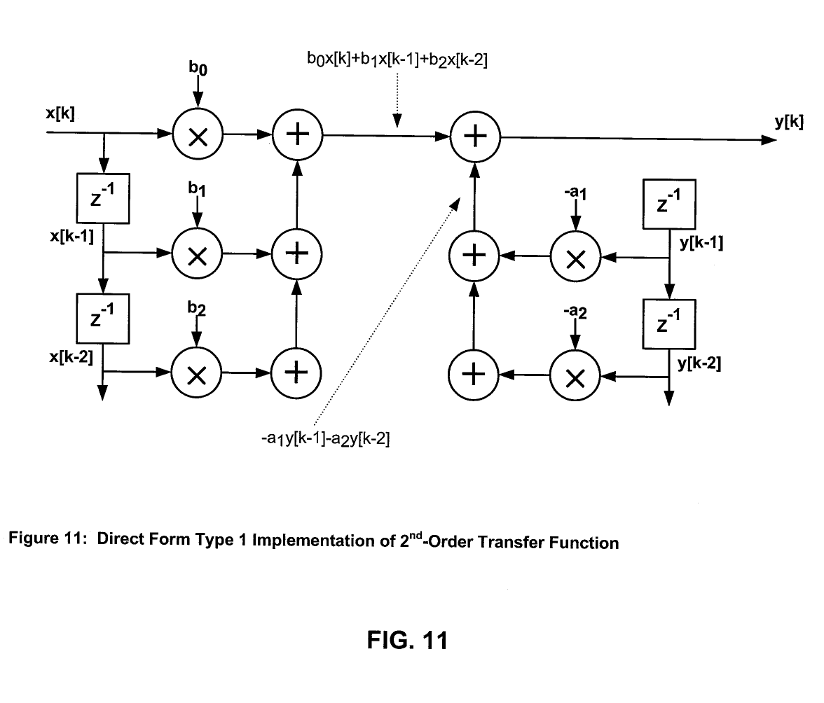

FIG. 11 illustrates the DF1 architecture for a second-order filter according to one embodiment of the present invention. As shown in FIG. 11, the multiplier coefficients in this filter structure correspond to the coefficients in the transfer function and in the difference equation above. The blocks marked with the symbol z−1 are delay registers, the outputs of which are required at every step of the computation. The outputs of these registers are termed state variables and memory is allocated for them in some embodiments of digital signal processing method 100. The output of the digital filter is computed as follows:
Initially, every one of the state variables is set to zero. In other words,

x[−1]=x[−2]=y[−1]=y[−2]=0.
At time k=0 the following computation is done, according to FIG. 11:

y[0]=b₀x[0]+b₁x[−1]+b₂x[−2]−a₁y[−1]−a₂y[−2].
Then, the registers are then updated so that the register marked by x[k−1] now holds x[0], the register marked by x[k−2] now holds x[−1], the register marked by y[k−1] holds y[0], and the register marked by y[k−2] holds y[−1].
At time k=1 the following computation is done:

y[1]=b₀x[1]+b₁x[−0]+b₂x[−1]−a₁y[0]−a₂y[−1].
Then, the register update is again completed so that the register marked by x[k−1] now holds x[1], the register marked by x[k−2] now holds x[0], the register marked by y[k−1] holds y[1], and the register marked by y[k−2] holds y[0].
This process is then repeated over and over for all instants k: A new input, x[k], is brought in, a new output y[k] is computed, and the state variables are updated.

In general, then, the digital filtering operation can be viewed as a set of multiplications and additions performed on a data stream x[0], x[1], x[2], . . . using the coefficients b0, b1, b2, a1, a2 and the state variables x[k−1], x[k−2], y[k−1], y[k−2].

The manifestation of this in specific situations is instructive. Examination of the bell filter that constitutes the fundamental building-block of graphic equalizer 107 is helpful. As discussed above, the bell filter is implemented with a sampling frequency Fs, gain G at a center frequency fc, and quality factor Q as

$$H ( z ) = \frac{1}{2} ( 1 + G ) A ( z ) + \frac{1}{2} ( 1 - G )$$

where A(z) is an allpass filter defined by

$$A ( z ) = \frac{{k}_{2} + {k}_{1} ( 1 + {k}_{2} ) {z}^{- 1} + {z}^{- 2}}{1 + {k}_{1} ( 1 + {k}_{2} ) {z}^{- 1} + {k}_{2} {z}^{- 2}}$$

where k1 and k2 are computed from fc and Q via the equations

$${k}_{1} = \frac{1 - tan ( \frac{π \text{?}}{{QF}_{s}} )}{1 + tan ( \frac{π \text{?}}{{QF}_{s}} )}$$

$$and$$

$${k}_{2} = - cos ( 2 π {f}_{c} / {F}_{s} )$$

$$\text{?} \text{indicates text missing or illegible when filed}$$

The values k1 and k2 are pre-computed and stored in a table in memory. To implement a filter for specific values of Q and fc, the corresponding values of k1 and k2 are looked up in this table. Since there are eleven specific values of fc and sixteen specific values of Q in the algorithm, and the filter operates at a single sampling frequency, Fs, and only k2 depends on both fc and Q, the overall storage requirements for the k1 and k2 coefficient set is quite small (11×16×2 words at worst).

Observe from the equation above for A(z) that its coefficients are symmetric. That is, the equations can be re-written as

$$A ( z ) = \frac{{z}^{- 2} + geq\_b 1 {z}^{- 1} + geq\_b 0}{1 + geq\_b 1 {z}^{- 1} + geq\_b 0 {z}^{- 2}}$$

$$where$$

$$geq\_b 0 = {k}_{2}$$

$$and$$

$$geq\_b 1 = {k}_{1} ( 1 + {k}_{2} ) .$$

Observe that A(z) as given in the above equation implies the difference equation

y[k]=geq_{—}b0x[k]+geq_{—}b1x[k−1]+x[k−2]−geq_{—}b1y[k−1]−geq_{—}b0y[k−2],

which can be rearranged to yield

y[k]=geq_{—}b0x[k]−y[k−2])+geq_{—}b1(x[k−1]−y[k−1])+x[k−2]

In a specific embodiment, the state variables may be stored in arrays xv[ ] and yv[ ] with xv[0] corresponding to x[k−2], xv[1] corresponding to x[k−1], yv[0] corresponding to y[k−2] and yv[1] corresponding to y[k−1]. Then the following code-snippet implements a single step of the allpass filter:

```
void allpass(float *xv, float *yv, float *input, float *output)
{
  *output = geq_b0 * (*input − yv[0]) + geq_b1 * (xv[1] − yv[1]) +
  xv[0]
  xv[0] = xv[1]; \\ update
  xv[1] = *input; \\ update
  yv[0] = yv[1]; \\update
  yv[1] = *output; \\update
}
```

Now the loop must be incorporated around the allpass filter as per the equations above. This is trivially realized by the following:

```
void bell(float *xv, float *yv, float gain, float *input, float *output)
{
  allpass(xv, yv, input, output);
  *output = 0.5 * (1.0−gain) * (*output) + 0.5 * (1.0+gain) * (*input);
}
```

More concisely, the previous two code snippets can be combined into a single routine that looks like this:

```
void bell(float *xv, float *yv, float gain, float *input, float *output)
{
  float ap_output = geq_b0 * (*input − yv[0])
  + geq_b1 * (xv[1] − yv[1]) + xv[0]
  xv[0] = xv[1]; \\ update
  xv[1] = *input; \\ update
  yv[0] = yv[1]; \\update
  yv[1] = *output; \\update
  *output = 0.5 * (1.0−gain) * ap_output + 0.5 * (1.0+gain) * (*input);
}
```

The first-order filter will now be examined in detail. These filters can be described by the transfer function

$$H ( z ) = \frac{{b}_{0} + {b}_{1} {z}^{- 1}}{1 + {a}_{1} {z}^{- 1}} ,$$

which corresponds to the difference equation

y[k]=b₀x[k]+b₁x[k−1]−a₁y[k−1].

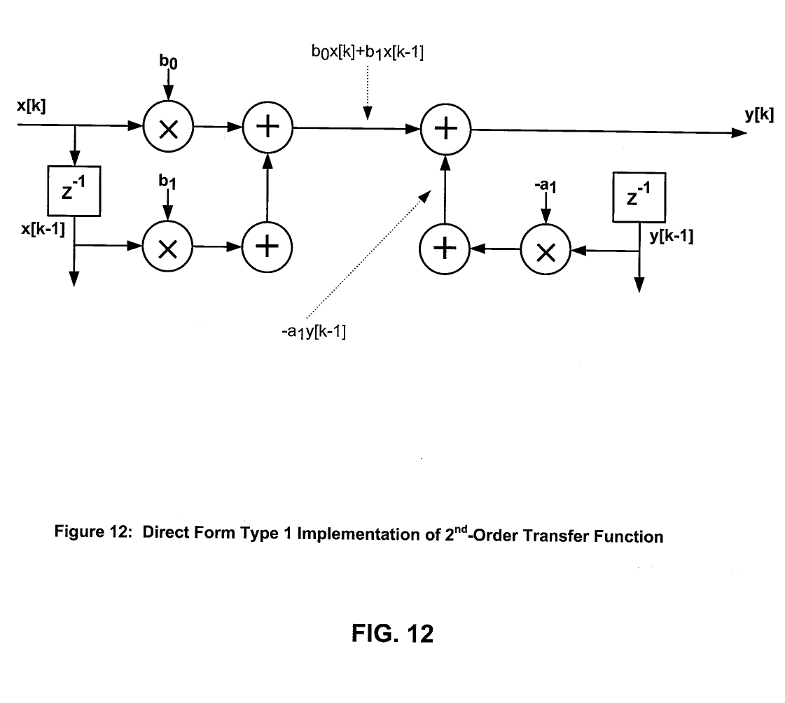

FIG. 12 illustrates the DF1 architecture for a first-order filter according to one embodiment of the present invention. Referring now to FIG. 12, the multiplier coefficients in this filter structure correspond in a clear way to the coefficients in the transfer function and in the difference equation. The output of the digital filter is computed as follows:
Initially, every one of the state variables is set to zero. In other words,

x[−1]=y[−1]=0.
At time k=0 the following computation is done, according to FIG. 11:

y[0]=b₀x[0]+b₁x[−1]−a₁y[−1].
Then, the registers are then updated so that the register marked by x[k−1] now holds x[0], and the register marked by y[k−1] holds y[0].
At time k=1 the following computation is done:

y[1]=b₀x[1]+b₁x[0]−a₁y[0]
Then, the register update is again completed so that the register marked by x[k−1] now holds x[1] and the register marked by y[k−1] holds y[1].
This process is then repeated over and over for all instants k: A new input, x[k], is brought in, a new output y[k] is computed, and the state variables are updated.

In general, then, the digital filtering operation can be viewed as a set of multiplications and additions performed on a data stream x[0], x[1], x[2], . . . using the coefficients b0, b1, a1 and the state variables x[k−1], y[k−1].

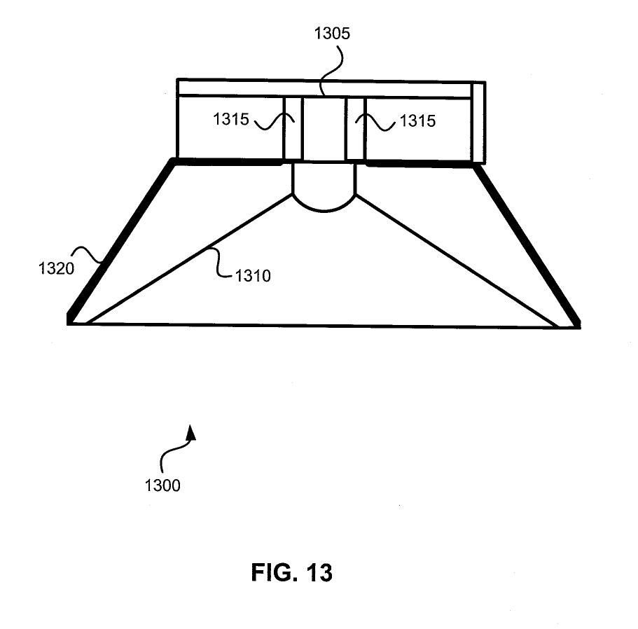

FIG. 13 is an illustration of an exemplary speaker 1300. The speaker 1300 includes a magnet 1305, a cone 1310, a voice coil 1315, and a basket 1320. Speaker 1300 may be operatively coupled to or otherwise associated with an audio source such as an amplifier, receiver, cellular telephone, or any other device capable of producing audio signals. The speaker 1300 may also be operatively coupled to a DSP.

In a traditional speaker, the material characteristics of the magnet 1305, the cone 1310, the voice coil 1315, and the basket 1320 may be carefully selected such that the speaker has a good (or high) frequency response. For example, the basket 1320 may be made with a material that is sufficiently sturdy to support a diaphragm, size, and shape of the magnet 1305, and the size and shape of the voice coil 1315. The size of the voice coil 1305—a factor that ultimately determines the power of the voice coil 1305—is typically selected with regard to the size of the magnet 1305, which in turn is determined by the overall size of the speaker 1300. Thus, traditional speakers are designed such that they yield a good and broad frequency response by utilizing materials that conform with each other (i.e., matched components). A speaker having a broad frequency response is a speaker having a good frequency response in the low, medium, and high frequency spectrum. If the materials selected are not well conformed with each other (i.e., mismatched), the speaker may be dampened, which may lead to poor (or low) frequency response.

In the speaker 1300, the basket 1320 can be made with aluminum, steel, titanium, any other metal, plastic, and plastic composite, in some examples. The basket 1320 is preferably strong enough to maintain its shape in a manner conducive to producing sound.

The magnet 1305 may comprise a permanent ferrite, ceramic, Alnico, or neodymium magnet. Generally, the size of the magnet 1305 determines the power and weight of the overall speaker 1300. For example, large high quality and heavy magnets may be used to produce powerful high quality speakers. In one embodiment, the speaker 1300 will have a magnet 1305 that is smaller (e.g., smaller than 10 oz) than magnets used in conventional high-fidelity speakers for a given application. In some embodiments, the speaker 1300 may comprise “rare earth magnets” such as neodymium, which is known to be highly lightweight.

The speaker 1300 may comprise a magnet 1305 that is less expensive (e.g., a magnet that is of degraded strength) than other magnets of a given mass which may be used in conventional high-fidelity speaker designs of the prior art. For example, the size of the magnet 1305 and the size of the voice coil 1315 may be directly related. Large voice coils 1315 may be needed in order to generate sufficient power to interact with a large magnet 1305. In other words, the stronger the magnetic field of the permanent magnet 1305, the larger voice coil 1315 is required to produce a sufficiently strong electromagnetic field to interact with the field of the permanent magnet 1305. Similarly, a small speaker may use a smaller magnet 1305 that requires a small voice coil 1315. Using a large voice coil 1315 with a small magnet 1305 may overload and destroy the speaker.

Generally, the voice coil 1315 may be created by winding a metal wire around a core. In speaker 1300, the wire may be wound around a sleeve. The magnet 1305 may be placed within the sleeve. The wire of voice coil 1315 may comprise many different materials such as copper or aluminum. The latter is used most often in conventional speakers.

The cone 1310 may comprise a light, stiff, and well damped material. Further, the speaker 1300 may include the cone 1310 that is, corresponding to the smaller magnet 1305, likewise of smaller size than for a conventional high-fidelity speaker of a given application. In some embodiments, the speaker 1300 may include a cone 1310 that comprises a less expensive grade or quality than conventional cellulose fiber cone papers. In one example, the cone 1310 comprises organic fibers and minerals like Kapok, Mica; synthetic fibers such as carbon fiber, glass fiber, polypropylene fiber, Kevlar fiber; rubber, Santoprene, or cloth.

The speaker 1300 may include a spider at the base of the cone 1310 that is of a different size than that of conventional high-fidelity speaker designs. The spider may be twice as wide as corrugations in a surrounding cone. Those skilled in the art will appreciate that the spider may be greater than twice as wide as the corrugations in the surrounding cone or, alternately, less than twice as wide.

In some embodiments, the speaker 1300 may be constructed of a basket 1320 having a lighter mass than that which is used in conventional high-fidelity speaker designs. Further, surrounds of the speaker 1300 may be composed of low grade rubbers, butylene, plastics, composites, or glues that connect the cone 1310 to the basket 1320 of the speaker 1300.

In some embodiments, the driver of the speaker 1300 may utilize mismatched and larger windings in the driver engine. Such variation in windings may alleviate power-handling requirements that may degrade the frequency response of the speaker 1300.

The voice coil 1315 attached to the audio driver may be of a different size than that of a conventional high-fidelity speaker. Such variation in voice coil 1315 size may be a part of a lighter design and inexpensive construction of the speaker 1300. The variation in the voice coil 1315 size may degrade the frequency response of the speaker 1300 by enabling greater power handling and extended throw of the driver. In some embodiments, the voice coil 1315 may be composed of a different metal other than convention coils of composed, Nomex, Aluminum, or Kapton, in order to further calibrate the power handling requirements of the speaker 1300.

The lighter mass and use of lower grade materials may result in a poor frequency response, which may be improved through the use of digital signal processing (DSP) technology on the source signal. In some embodiments, frequency response compensation may be achieved by use of a DSP, which may be executable on a computer chip, such as, without limitation, a digital signal processor. The digital signal processor may comprise one or more software and/or hardware modules working alone or in combination to execute a particular method. In some embodiments, such a chip may be one part of a larger device such as, without limitation, a radio, MP3 player, cell phone, navigation system, television, DVD player, or computer.

From time-to-time, some embodiments are described herein in terms of example or embodiment environments. Description in terms of these environments is provided to allow the various features and embodiments to be portrayed in the context of an exemplary application. After reading this description, it will become apparent to one of ordinary skill in the art how the invention can be implemented in different and alternative environments.

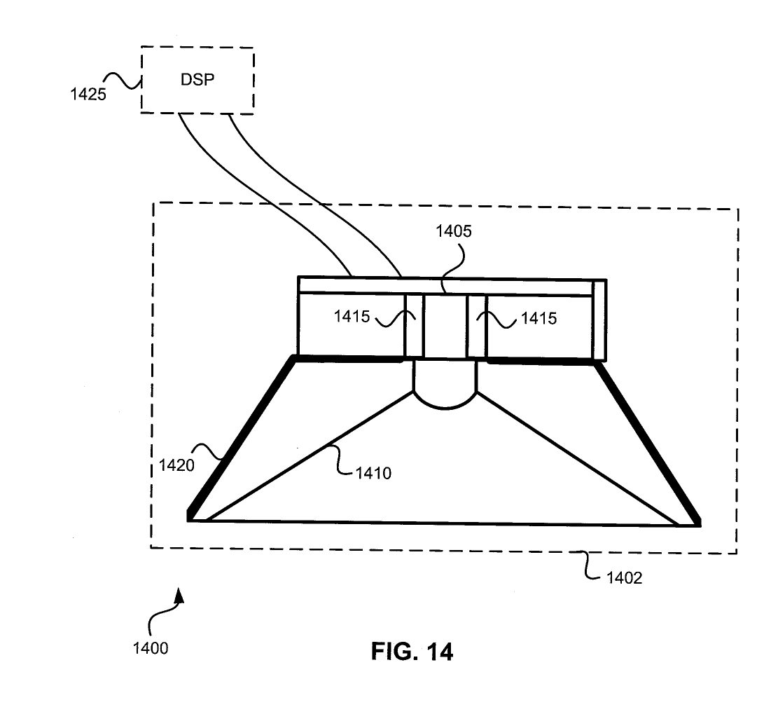

FIG. 14 is an illustration of an exemplary audio system 1400 including a speaker 1402 with mismatched components and a DSP 1425 coupled with the speaker 1402. The mismatched components of speaker 1402 may have a poor frequency response by, for example, using inexpensive and/or lightweight materials and other deficient physical specifications as described herein. In one embodiment, speaker 1402 comprises an underrated magnet 1405 and basket 1420 mass, as compared to those used in conventional speaker designs. As a result of the underrated magnet 1405 and basket 1420 mass, the speaker 1402 may have a lighter driver with relatively poor frequency response and deficient physical specifications. The DSP 1425 may compensate for the physical deficiencies and poor frequency response of the driver of speaker 1402.

The speaker 1402 may comprise the magnet 1405, the cone 1410, the voice coil 1415, and the basket 1420. Even though the mismatched components of the speaker 1402 may have a poor frequency response, the overall system 1400 may be configured to have a good frequency response (high and broad frequency response) with the aid of the DSP 1425. In this way, one or more inexpensive materials may be used to construct speaker 1402 to save money, to increase profit, and to decrease weight. Additionally, in various embodiments, engineers may focus on the cost and safety aspects of the speaker 1402 rather than the frequency response of the components of the speaker 1402. For example, engineers may focus on using lighter and softer materials in designing the basket 1420 and the cone 1410 to make the speaker 1402 safer or to conform with the environment. This may be particularly useful in the transportation application where the speaker 1402 is mounted in the passenger compartment such as on or in the headliner or other interior portions of a vehicle.

The cone 1410 and the basket 1420 may comprise materials that would normally not be used in a conventional speaker such as, for example, paper, flexible plastic, light sheet metals, and cardboard. Generally, the use of these materials or any combinations thereof to make the cone 1410 and the basket 1420 would be discouraged because the materials may be, for example, too dampened and too flexible. furthering some embodiments, cone 1410 may be made of a heavy type of paper and the basket 1420 can be made of a light plastic material that is semi-rigid. In a conventional speaker system, this usage of these kinds of materials is generally discouraged because the resultant speaker would be too dampened for lack of stiffness and hence, produce a lowered frequency response. However, in system 1400, the quality or frequency response of the components (alone or in combination) of speaker 1402 is compensated by DSP 1425. The functionality and operation of DSP 1425 will be discussed in detail below. DSP 1425 can be a separate standalone module or can be integrated into speaker 1402.

To reduce the weight and cost of the speaker 1402 for use in the same application (e.g., a sound system for a passenger compartment of a vehicle), smaller and cheaper grade magnets may be used instead of larger and higher quality magnets. Conventionally, smaller magnets may generally be used for a speaker with relatively small power requirements. This also means that smaller voice coils 1415 may be required for a speaker 1402 with a small magnet 1405 to avoid overdriving the speaker 1402, which may destroy or damage the speaker. The speaker 1402 may comprise any number of mismatched components. For example, to reduce the weight and cost of speaker 1402, a lighter weight and lower quality grade permanent magnet 1405 may be used in conjunction with an oversized voice coil 1415. This is against convention as an oversized voice coil may damage or destroy the speaker. However, this arrangement used in conjunction with the DSP 1425 may offer several advantages aside from cost savings. One of the advantages may be the ability to produce a more powerful speaker 1402 with a smaller magnet 1405. The larger voice coil 1415 may deliver more power than needed to the relatively smaller magnet 1405. Another advantage may be that the resultant speaker may be made more powerful than its conventional counterpart speaker of the same size and weight.

In the audio system 1400, DSP 1425 is configured to control the input signals to voice coil 1415 such that speaker 1402 will have a high frequency response while preventing the larger voice coil 1415 from overdriving the magnet 1405, which may damage or destroy other fragile components of speaker 1402 such as, for example, the cone 1410 and the basket 1420. In this way, DSP 1425 may enable speaker 1402 to operate close to its maximum physical limits without damaging or destroying the speaker 1402 and to produce a high quality sound (high frequency response) with one or more inexpensive and/or lower grade speaker components. The functionality and operation of DSP 1425 will now be described.

In some embodiments, the speaker 1402 may be associated with a headliner. The headliner may comprise a vehicle headliner. Further, the space that the second side of the headliner faces may comprise the cabin of a vehicle. The panel may comprise, or be separately attached to, one or more of the group consisting of: interior door moldings (front and/or rear), package tray, pillar/column/support structures, seat backs, dashboard, lift gates (rear doors), trunk, firewall (front or rear), and interior kick panels of a vehicle and specifically a motor vehicle such as an automobile. The speaker 1402 or driver may also be associated with any other panel or surface that can be excited to generate sound such as, but not limited to, panels and specifically the headliners in the interiors of vehicles. In some examples, vehicles may comprise airplanes, helicopters, trains, and boats, for example. This also includes other interior or exterior surfaces of, for example, vehicles, buildings or other objects, and specifically panels, including walls, ceilings, floors and children's toys, helmets, and furniture, for example, tables, chairs, sofas, and headboards for beds.

Those skilled in the art will appreciate the DSP 1425 may comprise any signal processor.

FIG. 15 is an illustration of a flow chart of an exemplary audio processing method 1500 implemented by the DSP 1425. The audio processing method 1500 may be executable on a computer chip, such as, without limitation, the DSP 1425. The DSP 1425 may comprise one or more software and hardware modules working alone or in combination to execute method 1500. In one embodiment, such a chip may be one part of a larger device, such as, without limitation, a radio, MP3 player, game station, cell phone, television, or computer. Referring now to FIG. 15, method 1500 starts at step 1505 where an audio signal is received from a device such as from an audio system of vehicle.

In step 1510, the received audio signal can be conditioned prior to the main processing portion of method 1500. In one example, the received signal may be filtered to limit low frequencies in the audio signal. The received signal may also be gain adjusted to modify the gain level of the audio signal. This step may include a loudness adjusting step to compensate for loudness variations caused, for example, by the volume control of an output device. In this way, the conditioned signal may have a constant loudness and/or gain level before the main processing portion of method 1500 begins. Step 1510 may include one or more of the above filtering, gain, and loudness adjusting steps discussed above. Additionally, the loudness adjusting step will be discussed in further detail herein.

In one embodiment, the received signal may be filtered using a pre-input high pass filter. The cut off point of the pre-input high pass filter may be adjusted. In one example, the cut off point of the pre-input high pass filter may be adjusted from about 20 to about 200 Hz. The pre-input filter has a roll off (slope of gain over frequency curve). In one example, the pre-input filter may have a roll-off of about 20 dB per octave or more. Alternately, the pre-input filter may have a roll off of about 20 dB per octave or less.

The received signal may be gain adjusted by computing a loudness level of the received signal using a leaky integrator. For example, the leaky integrator may calculate a slow-moving envelop based on an integrated version of the rectified signal. Once the overall loudness is determined, the received signal can be gain boosted or reduced, for example using a expander or limiter based on a threshold or reference loudness, for example. In this way, the signal outputted at this stage may have a relatively constant loudness with respect to a reference or threshold level regardless of the loudness of the source (e.g., regardless of the volume of the audio source). Step 1510 may be optional.

In step 1515, the received signal or the conditioned signal from step 1510 may be filtered to obtain a signal having a generally flat power spectral density (i.e., the power or energy distribution in all frequencies is equal). Prior to step 1515, the energy spectral density of a signal from an audio source may not be equally distributed in all frequencies. The energy spectral density of the raw audio signal from step 1505 may not be flat. For example, the power or energy of a frequency range may increases or decreases with respect to another frequency range of the audio signal.

In one example, the power spectral density of the audio signal received from step 1505 is flattened by a high and low shelving filter set combination. Each of the filters may boost or reduce the signal up to about 12 dB, or less. In some embodiments, the crossover point between the high and low frequency filters is located at about 1000 hertz. The low shelving filter may leave all of the frequencies above the corner frequency unaltered, while boosting or cutting all frequencies below the corner frequency by a fixed amount (e.g., ×dB). In one example, the response of the low shelving filter in cut mode is at −3 dB at the corner frequency, whereas a low-shelving filter in boost mode may be specified such that the response at the corner frequency is at G−3 dB—namely, 3 dB down from maximum boost. In step 1515, the low shelving filter may be implemented using a weighted sum of high-pass and low-pass filters.

In some embodiments, the raw audio signal received from step 1505 may comprise a pink noise portion and a white noise portion. The pink noise portion may span the entire frequency spectrum of the raw audio signal. Pink noise has equal energy in each octave. The white noise portion may also span the entire frequency spectrum of the raw audio signal, however, white noise contains equal energy at all frequencies. For pink noise, lower frequencies contain more energy than in higher frequencies.

The low and high shelving filters may be configured to flatten the energy spectral density from the pink and white noise portion(s) of the raw audio signal. In some embodiments, the filters may be configured to remove more energy from lower frequencies of the raw audio signal. More energy may be stored in the lower frequencies of the pink noise portion of an audio signal. In one example, in step 1510, a low audible bass portion of the raw audio signal (taken at 100 Hz) may be reduced by about 10 dB. Similarly, the high audible treble portion (taken at 8 kHz) may be increased by about 8 dB, and the portions in between may be reduced or enhanced in a linearly proportional manner (i.e., the increase is a substantially linear function of frequency). In this way, the high-low shelving filter set may produce a generally flat energy spectral density across a wide range of frequencies (e.g., low audible bass to high audible treble frequencies).

In step 1520, a gain controller or compressor compresses the filtered signal to increase the dynamic range of the received audio signal. In one example, the gain controller is configured to alter the dynamic range of a signal by reducing the ratio between the signal's peak level and the signal's average level. A gain controller may be characterized by four quantities: the attack time, Tatt, the release time, Trel, the threshold, KT, and the ratio, r. In brief, the envelope of the signal may be tracked by an algorithm that gives a rough “outline” of the signal's level. Once that level surpasses the threshold, KT, for a period of time equal to Tatt, the gain controller may decrease the level of the signal by the ratio r dB for every dB above KT. Once the envelope of the signal falls below KT for a period equal to the release time, Trel, the gain controller may stop decreasing the level.

In step 1525, one or more filters further filters the compressed signal from step 1520 in order to convert the signal having a flat energy spectral density to a signal having a full frequency response (i.e., energy spectral density is no longer flat). On a high level, the signal with a flat energy spectral density may be reconstructed into a signal with a flat frequency response and having a variable energy spectral density. In one example, reconstruction can be accomplished using a set of low-high shelving filters that is a mirror image of the low-high shelving filter set in step 1515. In one example, all frequencies below the corner frequency are left unmodified, whereas frequencies above the corner frequency are boosted or cut by ‘x’ dB. Similar to the first low-high shelving filter set in step 1515, the second low-high filter set may have a crossover point at 1000 Hz. Each of the filters may boost or reduce the signal level by 12 dB, for example.

In step 1530, an equalizer processes the 3^{rd} filtered signal (i.e., the reconstructed signal from step 1525). The operational settings of the equalizer may be manually set by an audio engineer. The equalizer may allow an individual such as an audio engineer to finely tune and enhance the output signal based on various factors such as, but not limited to, the physical limitation of the speakers and the environment. For example, the equalizer may comprise a 10 band fully parametric equalizer. In some embodiments, the equalizer may have a number of second order filters and may comprise eleven cascading second order filters. In one example, each of the filters in the equalizer may boost or reduce the signal level by 18 dB or −12 dB, respectively. Those skilled in the art will appreciate that the quality factor of the band may be individually adjusted from about 0.4 to about 8.0, for example.

Each cascading second order filter may be a bell filter. The eleven second order filters may achieve a bell-shaped boost or cut at a fixed center frequency with the first filter centered, for example, at 30 Hz and the eleventh filter centered, for example, at 16000 Hz. All of the other filters in between the first and the eleventh filters may be centered at roughly one-octave intervals.

In some embodiments, a user interface may be preloaded with various equalizer settings for a variety of speaker and headset types. The user interface may enable the user to select the appropriate audio play back device. For example, the user may enter a specific code for a particular headset to calibrate the equalizer of the DSP 1425 for optimum near-studio audio quality output. The code can be included along with the operational manual of the speaker 1402 or can be located, for example, via the manufacturer of the speaker 1402 website.

In step 1535, the output signal from step 1530 may be further compressed. In some embodiments, a split band compressor may be used. In one example, the split band compressor may comprise a low frequency compressor that operates in the range of about 0 to about 500 Hz and a high frequency compressor that operates in the range of about 10 k to about 20 k Hz. For example, each compressor may have the following specifications: threshold of 0 to −52 dB; ratio of 1:1 to 800:1; make up gain of +12 dB to 90 dB; attack time of 0 to 99 ms; and release time of 0 to 495 ms. In some embodiments, one of the main functions of step 1535 is to allow the speaker 1402 or headset to operate in a range that is near its physical design limitations. Although not shown, the output signal from step 1535 may be further gain adjusted to compensate for any loudness/gain adjustment that was done in step 1510.

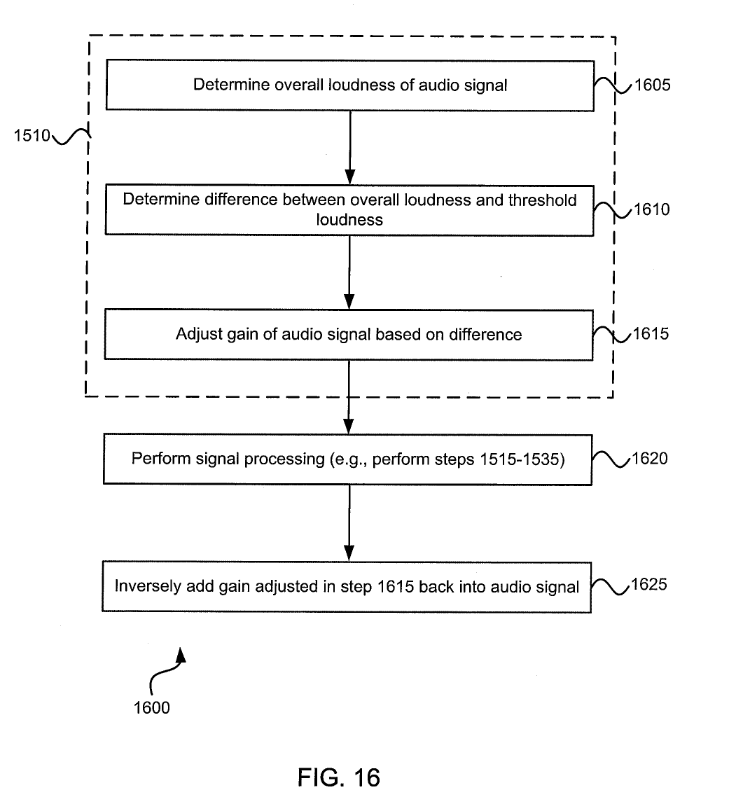

FIG. 16 is an illustration of an exemplary process flow of a portion of step 1510. A method 1600 for adjusting the loudness of an audio signal is shown. Method 1600 may be used in a system where the loudness of the audio source can be varied by a volume adjustment, such as an audio output from a portable music or video player or a portable gaming device. In some embodiments, an audio processing unit (e.g., DSP 1425) may be configured to work with an audio source having a prescribed gain or loudness value when performing steps 1515-1535 as described in FIG. 15. Thus, when the volume is substantially lowered or raised, downstream signal processing performed by the audio processing unit may be distorted because the loudness is not at the expected level. Thus, method 1600, in some embodiments, may be used to generate an output signal with a predetermined loudness regardless of the volume of the input audio signal. In this way, the audio processing unit may perform steps 1515-1535 as designed and without added distortion.

In step 1605, the overall loudness of the received signal from step 1505 is determined. In one example, a leaky integrator determines the overall loudness of the received signal. Those skilled in the art will appreciate that there are many methods to determine loudness.

In step 1610, the determined loudness may be compared with a threshold loudness. The threshold loudness may be manually set. In one example, the threshold loudness is based on the filters and the gain stages inside of the audio processing unit.

In step 1615, the gain of the raw audio signal may be adjusted based on the comparison from step 1610. In one example, if the loudness is above the threshold, the gain of the audio signal is reduced. The gain of the audio signal may be reduced using a limiter. Those skilled in the art will appreciate that many gain reduction methods may be used. In some embodiments, if the loudness is below the threshold, the gain of the audio signal may be increased. In one example, the gain may be increased with an expander. Alternately, other gain boosting methods may be used.

After the gain is adjusted in step 1615, the signal can be further processed in step 1620. For example, the signal can be further processed using steps 1515 to 1535 of method 1500. In a step 1625, the gain add or subtracted from the audio signal in step 1615 may be subtracted or added back in by an amount that is approximately or exactly inverse to the amount taken or added in step 1615. In this way, the original volume control may be mimicked at the end of method 1600.

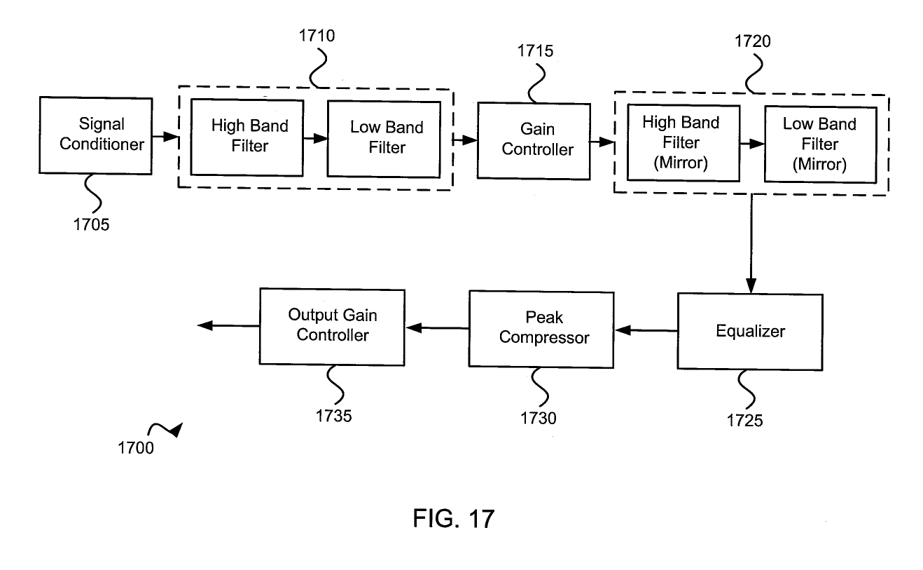

FIG. 17 is an illustration of an exemplary digital signal process. Method 1700 comprises the following stages: a signal conditioning stage 1705, first low-high shelve filtering stage 1710, a first gain controller stage 1715, a second low-high shelve filtering stage 1720, an equalizing stage 1725, a second compressor stage 1730, and an output gain adjustment stage 1735.

Similar to method 1500, methods 1600 and 1700 may be executable on a computer chip, such as, without limitation, a digital signal processor, or DSP. In one embodiment, such a chip may be one part of a larger audio device, such as, without limitation, a radio, MP3 player, game station, cell phone, television, computer, or public address system. In one such embodiment, digital signal processing method 1700 may be performed on the audio signal before it is outputted from the audio device. In some embodiments, digital signal processing method 1700 may be performed on the audio signal after it has passed through the source selector, but before it passes through the volume control.

The conditioner stage 1705 may provide a desired amount of gain in order to bring the input audio signal to step 1710 to a level that will prevent digital overflow at subsequent internal points in digital signal processing method 100. Each of the low-shelf filters in filter stages 1710 and 1720 may be a filter that has a nominal gain of, in one examples, about 0 dB for all frequencies above a certain frequency termed the corner frequency. For frequencies below the corner frequency, the low-shelving filter, in another example, has a gain of ±G dB, depending on whether the low-shelving filter is in boost or cut mode, respectively.

The audio signal from stage 1715 may be applied to the input of gain controller stage 1715. Gain controller stage 1715 may provide a degree of amplification which is inversely related to signal amplitude. Low amplitude portions of the signal may be provided with higher gain amplification than high amplitude portions with the result that the dynamic range of represented sounds may be lowered (quiet sounds would be raised; loud sounds would be lowered). The dynamic range may be reduced to about 10 dB or less. Those skilled in the art will appreciate that a variety of compressor circuits are known and can be utilized in this context.

The signal received at stage 1720 may be subjected to “mirror image” equalization in mirror image filtering stage 1720. At this stage, the bass portion of the signal may be increased, while the treble portion may be reduced. The low audible bass portion (100 Hz) may be increased up to 12 dB and high audible treble portion (10 kHz) may be reduced up to 12 dB. In one example, the low audible bass portion (100 Hz) may be increased about 10 dB and high audible treble portion (10 kHz) may be reduced about 8 dB. The intermediate portions of the signal may be reduced as a substantially linear function of frequency. In one example, the equalizer 1715 and the “mirror image” equalizer or gain controller 1715 are chosen so that they have equal and opposite effects.

After equalization, the processed audio signal may be applied to speaker system or headset, either directly or, in a one example, through a multiple-band equalizer for sound presentation. The speaker system, in some embodiments, may comprise small speakers (having magnets smaller than about 10 oz), for presentation of sound in a high-noise environment. Because the bass portion may be reduced before compression and enhanced after compression, the sound presented by the speakers may have a spectrum rich in bass tones and free of the muffling effect encountered in conventional compression. Since the dynamic range may be reduced by compression, the sound may be presented within the limited volume range between the about 80 dB noise floor and the about 110 dB threshold of unpleasant sensation.

In some embodiments, an optional power supply and a 10-band graphic equalizer for a specific speaker assembly further process the signal. The equalizer may be disposed, for example, at the output of mirror image equalizer 1720.

A peak compressor 1730 may further compress the signal. Further, an output gain controller 1735 may increase or decrease the gain before output the signal.

Unless defined otherwise, all technical and scientific terms used herein have the same meaning as is commonly understood by one of ordinary skill in the art to which this invention belongs. All patents, applications, published applications and other publications referred to herein are incorporated by reference in their entirety. If a definition set forth in this section is contrary to or otherwise inconsistent with a definition set forth in applications, published applications and other publications that are herein incorporated by reference, the definition set forth in this section prevails over the definition that is incorporated herein by reference.

The term tool can be used to refer to any apparatus configured to perform a recited function. For example, tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance on which software runs or in which hardware is implemented.

As used herein, the term module might describe a given unit of functionality that can be performed in accordance with one or more embodiments of the present invention. As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or embodied as separate modules, one of ordinary skill in the art will understand that these features and functionality can be shared among one or more common software and hardware elements, and such description shall not require or imply that separate hardware or software components are used to implement such features or functionality.

Where components or modules of the invention are implemented in whole or in part using software, in one embodiment, these software elements can be implemented to operate with a computing or processing module capable of carrying out the functionality described with respect thereto. One such example-computing module is shown in FIG. 6. Various embodiments are described in terms of this example-computing module 600. After reading this description, it will become apparent to a person skilled in the relevant art how to implement the invention using other computing modules or architectures.

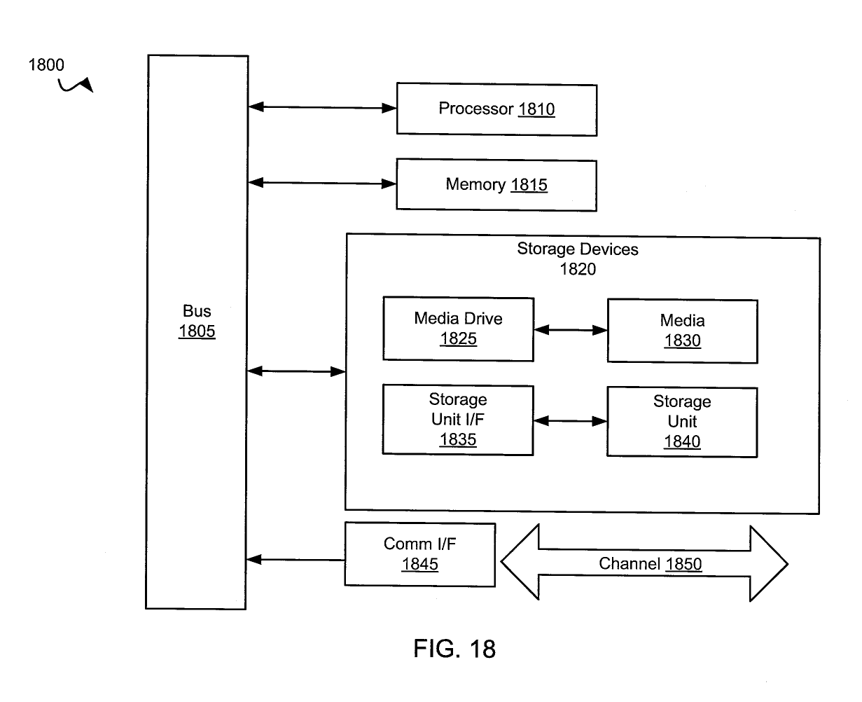

FIG. 18 is an illustration of an exemplary computer module 1800 in which a computer processing method may be implemented. Referring now to FIG. 18, computing module 1800 may represent, for example, computing or processing capabilities found within desktop, laptop and notebook computers, hand-held computing devices (PDA's, smart phones, cell phones, palmtops, etc.), mainframes, supercomputers, workstations or servers, music players, media players, ebook readers, or any other type of special-purpose or general-purpose computing devices as may be desirable or appropriate for a given application or environment. Computing module 1800 might also represent computing capabilities embedded within or otherwise available to a given device. For example, a computing module might be found in other electronic devices such as, for example, digital cameras, navigation systems, cellular telephones, portable computing devices, modems, routers, WAPs, and other electronic devices that might include some form of processing capability.

Computing module 1800 may include, for example, one or more processors or processing devices, such as a processor 1810. Processor 1810 may be implemented using a general-purpose or special-purpose processing engine such as, for example, a microprocessor, controller, or other control logic. In the example illustrated in FIG. 18, processor 1810 may be connected to a bus 1805 or other communication medium to facilitate interaction with other components of computing module 1800.

Computing module 1800 may also include one or more memory modules, referred to as main memory 1815. For example, preferably random access memory (RAM) or other dynamic memory, may be used for storing information and instructions to be executed by processor 1810. Main memory 1815 may also be used for storing temporary variables or other intermediate information during execution of instructions to be executed by processor 1810. Computing module 1800 may likewise include a read only memory (ROM) or other static storage device coupled to bus 1805 for storing static information and instructions for processor 1810.

The computing module 1800 may also include one or more various forms of information storage devices 1820, which may include, for example, a media drive 1825 and a storage unit interface 1835. The media drive 1825 may include a drive or other mechanism to support fixed or removable storage media 1830. The storage media 1830, may include, for example, a hard disk, a floppy disk, magnetic tape, cartridge, optical disk, a CD or DVD, or other fixed or removable medium that is read by, written to or accessed by media drive 1825. As these examples illustrate, the storage media 1830 may include a computer usable storage medium having stored therein particular computer software (e.g., instructions executable by a processor 1810 for performing a method) or data.

Information storage devices 1820 may include other similar instrumentalities for allowing computer programs or other instructions or data to be loaded into computing module 1800. Such instrumentalities may include, for example, a fixed or removable storage unit 1840 and an interface 1835. Examples of such storage units 1840 and interfaces 1835 may include a program cartridge and cartridge interface, a removable memory (for example, a flash memory or other removable memory module) and memory slot, a PCMCIA slot and card, and other fixed or removable storage units 1840 and interfaces 1835 that allow software and data to be transferred from the storage unit 1840 to computing module 1800.

Computing module 1800 may also include a communications interface 1845. Communications interface 1845 may be used to allow software and data to be transferred between computing module 1800 and external devices. Examples of communications interface 1845 might include a modem or softmodem, a network interface (such as an Ethernet, network interface card, WiMedia, 802.XX, WiMAX, LTE or other interface), a communications port (such as for example, a USB port, IR port, RS232 port Bluetooth interface, or other port), or other communications interface. Software and data transferred via communications interface 1845 may be carried on signals, which can be electronic, electromagnetic, optical or other signals capable of being exchanged by a given communications interface 1845. These signals may be provided to communications interface 1845 via a channel 1828. This channel 1828 may carry signals and may be implemented using a wired or wireless medium. Some examples of a channel may include a phone line, a cellular link, an RF link, an optical link, a network interface, a local or wide area network, and other wired or wireless communications channels.

In this document, the terms “computer program medium,” “computer usable medium,” and “computer readable medium,” are used to generally refer to media such as, for example, a memory module, storage unit 1820, and/or media 1830. Instructions embodied on the medium, are generally referred to as “computer program code” or a “computer program product” (which may be grouped in the form of computer programs or other groupings). When executed (e.g., by a processor), such instructions might enable the computing module 1800 to perform features or functions of the present invention as discussed herein.

Referring back to the equations above, a first-order shelving filter can be created by applying the equation

$$A ( z ) = \frac{{k}_{2} + {k}_{1} ( 1 + {k}_{2} ) {z}^{- 1} + {z}^{- 2}}{1 + {k}_{1} ( 1 + {k}_{2} ) {z}^{- 1} + {k}_{2} {z}^{- 2}}$$

to the first-order allpass filter A(z), where

$$A ( z ) = \frac{α - {z}^{- 1}}{1 - α {z}^{- 1}}$$

where α is chosen such that

$$α = \frac{( 1 - sin ( \frac{2 π \text{?}}{\text{?}} ) )}{cos ( \frac{2 π \text{?}}{\text{?}} )}$$

$$\text{?} \text{indicates text missing or illegible when filed}$$

where fc is the desired corner frequency and Fs is the sampling frequency. The allpass filter A(z) above corresponds to the difference equation

y[k]=αx[k]−x[k−1]+αy[k−1].

If allpass coefficient α is referred to as allpass coef and the equation terms are rearranged, the above equation becomes

y[k]=allpass_coe f(x[k]+y[k−1])−x[k−1].

This difference equation corresponds to a code implementation of a shelving filter that is detailed below.

One specific software implementation of digital signal processing method 100 will now be detailed.

Input gain adjustment 101 and output gain adjustment 109, described above, may both be accomplished by utilizing a “scale” function, implemented as follows:

```
void scale(gain, float *input, float *output)
{
  for (i = 0; i < NSAMPLES; i++)
  {
    *output++ = inputGain * (*input++);
  }
}
```

First low shelf filter 102 and second low shelf filter 105, described above, may both be accomplished by utilizing a “low_shelf” function, implemented as follows:

```
void low_shelf(float *xv, float *yv, float *wpt, float *input, float *output)
{
  float l;
  int i;
  for (i = 0; i < NSAMPLES; i++)
  {
    if (wpt[2] < 0.0) \\ cut mode, use conventional realization
    { \\ allpass_coef = alpha
      yv[0] = ap_coef * (*input) + (ap_coef * ap_coef − 1.0) * xv[0];
      xv[0] = ap_coef * xv[0] + *input;
      *output++ = 0.5 * ((1.0 + wpt[0]) * (*input++) +
      (1.0 − wpt[0]) * yv[0]);
    }
    else \\ boost mode, use special realization
    {
      l = (ap_coef * ap_coef − 1.0) * xv[0];
      *output = wpt[1] * ((*input++) − 0.5 * (1.0 − wpt[0]) * 1);
      xv[0] = ap_coef * xv[0] + *output++;
    }
  }
}
```

As this function is somewhat complicated, a detailed explanation of it is proper. First, the function declaration provides:

void low_shelf(float *xv, float *yv, float *wpt, float *input, float *output)
The “low_shelf” function takes as parameters pointers to five different floating-point arrays. The arrays xv and yv contain the “x” and “y” state variables for the filter. Because the shelving filters are all first-order filters, the state-variable arrays are only of length one. There are distinct “x” and “y” state variables for each shelving filter used in digital signal processing method 100. The next array used is the array of filter coefficients “wpt” that pertain to the particular shelving filter. wpt is of length three, where the elements wpt[0], wpt[1], and wpt[2] describe the following:

wpt[0]=G

wpt[1]=2[(1+G)+α(1−G)]⁻¹

wpt[2]=−1 when cutting, 1 when boosting

and α is the allpass coefficient and G is the shelving filter gain. The value of α is the same for all shelving filters because it is determined solely by the corner frequency (it should be noted that and all four of the shelving filters in digital signal processing method 100 have a corner frequency of 1 kHz). The value of G is different for each of the four shelving filters.

The array “input” is a block of input samples that are fed as input to each shelving filter, and the results of the filtering operation are stored in the “output” array.

The next two lines of code,

float l;
int i;
allocate space for a loop counter variable, i, and an auxiliary quantity, l, which is the quantity 10[k] from FIG. 9.

The next line of code,

for (i=0; i<NSAMPLES; i++)
performs the code that follows a total of NSAMPLES times, where NSAMPLES is the length of the block of data used in digital signal processing method 100.

This is followed by the conditional test

if (wpt[2]<0.0)
and, recalling the equations discussed above, wpt[2]<0 corresponds to a shelving filter that is in “cut” mode, whereas wpt[2]>=0 corresponds to a shelving filter that is in “boost” mode. If the shelving filter is in cut mode the following code is performed:

```
if (wpt[2] < 0.0) \\ cut mode, use conventional realization
{  \\ allpass_coef = alpha
    yv[0] = ap_coef * (*input) + (ap_coef * ap_coef − 1.0) * xv[0];
    xv[0] = ap_coef * xv[0] + *input;
    *output++ = 0.5 * ((1.0 + wpt[0]) * (*input++) + (1.0 −
    wpt[0]) * yv[0]);
}
```

The value xv[0] is simply the state variable x[k] and yv[0] is just yv[k]. The code above
is merely an implementation of the equations

y[k]=α·in[k]+(α²−1)·x[k]

x[k]=α·x[k]+in[k]

out[k]=1/2((1+G)·in[k]+(1−G)·y[k]

If the shelving filter is in cut mode the following code is performed:

```
else \\ boost mode, use special realization
{
  l = (ap_coef * ap_coef − 1.0) * xv[0];
  *output = wpt[1] * ((*input++) − 0.5 * (1.0 − wpt[0]) * l);
  xv[0] = ap_coef * xv[0] + *output++;
}
```

which implements the equations

l₀[k]=(α²−1)·x[k]

out[k]=2[(1+G)+α(1−G)]⁻¹·(in[k]−1/2(1−G)l₀[k])

x[k]=α·x[k−1]+out[k]

First high shelf filter 103 and second high shelf filter 106, described above, may both be accomplished by utilizing a “high-shelf” function, implemented as follows:

```
void high_shelf(float *xv, float *yv, float *wpt, float *input, float
*output)
{
  float l;
  int i;
  for (i = 0; i < NSAMPLES; i++)
  {
    if (wpt[2] < 0.0) \\ cut mode, use conventional realization,
    { \\ allpass_coef = alpha
      yv[0] = allpass_coef * (*input) + (allpass_coef *
    allpass_coef − 1.0) * xv[0];
      xv[0] = allpass_coef * xv[0] + *input;
      *output++ = 0.5 * ((1.0 + wpt[0]) * (*input++) − (1.0 −
      wpt[0]) * yv[0]);
    }
    else \\ boost mode, use special realization
    {
      l = (allpass_coef * allpass_coef − 1.0) * xv[0];
      *output = wpt[1] * ((*input++) + 0.5 * (1.0 − wpt[0]) * l);
      xv[0] = allpass_coef * xv[0] + *output++;
    }
  }
}
```

Implementing the high-shelving filter is really no different than implementing the low-shelving filter. Comparing the two functions above, the only substantive difference is in the sign of a single coefficient. Therefore, the program flow is identical.

Graphic equalizer 107, described above, may be implemented using a series of eleven calls to a “bell” filter function, implemented as follows:

```
void bell(float *xv, float *yv, float *wpt, float *input, float *output)
{
  float geq_gain = wpt[0]; \\ G
  float geq_b0 = wpt[1]; \\ k2
  float geq_b1 = wpt[2]; \\ k1(1+k2)
  float ap_output;
  int i;
  for (i = 0; i < NSAMPLES; i++)
  {
    ap_output = geq_b0 * (*input − yv[0]) + geq_b1 *
    (xv[1] − yv[1]) + xv[0];
    xv[0] = xv[1]; \\ update
    xv[1] = *input; \\ update
    yv[0] = yv[1]; \\update
    yv[1] = *output; \\update
    *output++ = 0.5 * (1.0−gain) * ap_output + 0.5 * (1.0+gain) *
    (*input++);
  }
}
```

The function bell( ) takes as arguments pointers to arrays xv (the “x” state variables), yv (the “y” state variables), wpt (which contains the three graphic EQ parameters G, k2, and k1 (1+k2)), a block of input samples “input”, and a place to store the output samples. The first four statements in the above code snippet are simple assignment statements and need no explanation.

The for loop is executed NSAMPLES times, where NSAMPLES is the size of the block of input data. The next statement does the following:

$$ap\_output = geq\_b 0 * (* input - yv [ 0 ] ) + geq\_b1 * ( xv [ 1 ] - yv [ 1 ] ) + xv [ 0 ]$$

The above statement computes the output of the allpass filter as described above. The next four statements do the following:
xv[0]=xv[1];
shifts the value stored in x[k−1] to x[k−2].
xv[1]=*input;
shifts the value of input[k] to x[k−1].
yv[0]=yv[1];
shifts the value stored in y[k−1] to y[k−2].
yv[1]=*output;
shifts the value of output[k], the output of the allpass filter, to y[k−1].

Finally, the output of the bell filter is computed as

*output++=0.5*(1.0−gain)*ap_output+0.5*(1.0+gain)*(*input++);

First compressor 104 and second compressor 108, described above, may be implemented using a “compressor” function, implemented as follows:

```
void compressor(float *input, float *output, float *wpt, int index)
{
  static float level;
  float interp, GR, excessGain, L, invT, ftempabs;
  invT = wpt[2];
  int i, j;
  for (i = 0; i < NSAMPLES; i ++)
  {
    ftempabs = fabs(*input++);
    level = (ftempabs >= level)? wpt[0] * (level − ftempabs) +
    ftempabs : wpt[1] * (level − ftempabs) + ftempabs;
    GR = 1.0;
    if (level * invT > 1.0)
    {
      excessGain = level *invT;
      interp = excessGain − trunc(excessGain);
      j = (int) trunc(excessGain) − 1;
      if (j < 99)
      {
        GR = table[index][j] + interp * (table[index][j+1] −
        table[index][j]);
        // table[ ][ ] is the exponentiation table
      }
      else
      {
        GR = table[index][99];
      }
    }
    *output++ = *input++ * GR;
  }
}
```

The compressor function takes as input arguments pointers to input, output, and wpt arrays and an integer, index. The input and output arrays are used for the blocks of input and output data, respectively. The first line of code,

static float level;

allocates static storage for a value called “level” which maintains the computed signal level between calls to the function. This is because the level is something that needs to be tracked continuously, for the entire duration of the program, not just during execution of a single block of data.

The next line of code,

float interp, GR, excessGain, L, invT, ftempabs;
allocates temporary storage for a few quantities that are used during the computation of the compressor algorithm; these quantities are only needed on a per-block basis and can be discarded after each pass through the function.

The next line of code,

invT=wpt [2],
extracts the inverse of the compressor threshold, which is stored in wpt[2], which is the third element of the wpt array. The other elements of the wpt array include the attack time, the release time, and the compressor ratio.

The next line of code indicates that the compressor loop is repeated NSAMPLES times. The next two lines of code implement the level computation as per the equations above. To see this, notice that the line

level=(ftempabs>=level)?wpt[0]*(level−ftempabs)+ftempabs:wpt[i]*(level−ftempabs)+ftempabs;

is equivalent to the expanded statement

```
if (ftempabs >= level)
{
  level = wpt[0] * (level − ftempabs) + ftempabs;
}
else
{
  level = wpt[1] * (level − ftempabs) + ftempabs
}
```

which is what is needed to carry out the above necessary equation, with wpt[0] storing the attack constant αatt and wpt[1] storing the release constant arel.

Next, it can be assumed that the gain reduction, GR, is equal to unity. Then the comparison

if (level*invT>1.0)

is performed, which is the same thing as asking if level >T, i.e., the signal level is over the threshold. If it is not, nothing is done. If it is, the gain reduction is computed. First, the excess gain is computed as

excessGain=level*invT;

as calculated using the equations above. The next two statements,

interp=excessGain−trunc(excessGain)

j=(int)trunc(excessGain)−1;

compute the value of index into the table of exponentiated values, as per the equations above. The next lines,

```
if (j < 99)
{
  GR = table[index][j] + interp * (table[index][j+1] − table[index][j]);
  // table[ ][ ] is the exponentiation table
}
else
{
  GR = table[index][99];
}
```

implement the interpolation explained above. The two-dimensional array, “table,” is parameterized by two indices: index and j. The value j is simply the nearest integer value of the excess gain. The table has values equal to

$$table [ index ] [ j ] = {( j )}^{\frac{1 - index}{index}}$$

which can be recognized as the necessary value from the equations above, where the “floor” operation isn't needed because j is an integer value. Finally, the input is scaled by the computed gain reduction, GR, as per

*output++=*input++*CR;

and the value is written to the next position in the output array, and the process continues with the next value in the input array until all NSAMPLE values in the input block are exhausted.

It should be noted that in practice, each function described above is going to be dealing with arrays of input and output data rather than a single sample at a time. This doesn't really change the program much, as hinted by the fact that the routines above were passed their inputs and outputs by reference. Assuming that the algorithm is handed a block of NSAMPLES in length, the only modification needed to incorporate arrays of data into the bell-filter functions is to incorporate looping into the code as follows:

```
void bell(float *xv, float *yv, float gain, float *input, float *output)
{
  float ap_output;
  int i;
  for (i = 0; i < NSAMPLES; i++)
  {
    ap_output = geq_b0 * (*input − yv[0])
    + geq_b1 * (xv[1] − yv[1]) + xv[0]
    xv[0] = xv[1]; \\ update
    xv[1] = *input; \\ update
    yv[0] = yv[1]; \\update
    yv[1] = *output; \\update
    *output++ = 0.5 * (1.0−gain) * ap_output + 0.5 * (1.0+gain) *
    (*input++);
  }
}
```

Digital signal processing method 100 as a whole, may be implemented as a program that calls each of the above functions, implemented as follows:

// it is assumed that floatBuffer contains a block of
// NSAMPLES samples of floating-point data.
// The following code shows the instructions that
// are executed during a single pass
scale(inputGain, floatBuffer, floatBuffer);
low_shelf(xv1_ap, yv1_ap, &working_table[0], floatBuffer,
floatBuffer);
high_shelf(xv2_ap, yv2_ap, &working_table[3], floatBuffer,
floatBuffer);
compressor(floatBuffer, floatBuffer, &working_table[6], ratio1Index);
low_shelf(xv3_ap_left, yv3_ap_left, xv3_ap_right, yv3_ap_right,
&working_table[11], floatBuffer, floatBuffer);
high_shelf(xv4_ap_left, yv4_ap_left, xv4_ap_right, yv4_ap_right,
&working_table[14], floatBuffer, floatBuffer);
bell(xv1_geq, yv1_geq, &working_table[17], floatBuffer, floatBuffer);
bell(xv2_geq, yv2_geq, &working_table[20], floatBuffer, floatBuffer);
bell(xv3_geq, yv3_geq, &working_table[23], floatBuffer, floatBuffer);
bell(xv4_geq, yv4_geq, &working_table[26], floatBuffer, floatBuffer);
bell(xv5_geq, yv5_geq, &working_table[29], floatBuffer, floatBuffer);
bell(xv6_geq, yv6_geq, &working_table[32], floatBuffer, floatBuffer);
bell(xv7_geq, yv7_geq, &working_table[35], floatBuffer, floatBuffer);
bell(xv8_geq, yv8_geq, &working_table[38], floatBuffer, floatBuffer);
bell(xv9_geq, yv9_geq, &working_table[41], floatBuffer, floatBuffer);
bell(xv10_geq, yv10_geq, &working_table[44], floatBuffer,
floatBuffer);
bell(xv11_geq, yv11_geq, &working_table[47], floatBuffer,
floatBuffer);
compressor(floatBuffer, floatBuffer, &working_table[50], ratio1Index);
scale(outputGain, floatBuffer, floatBuffer);

As can be seen, there are multiple calls to the scale function, the low_shelf function, the high_shelf function, the bell function, and the compressor function. Further, there are references to arrays called xv1, yv1, xv2, yv2, etc. These arrays are state variables that need to be maintained between calls to the various routines and they store the internal states of the various filters in the process. There is also repeated reference to an array called working_table. This table holds the various pre-computed coefficients that are used throughout the algorithm. Algorithms such as this embodiment of digital signal processing method 100 can be subdivided into two parts: the computation of the coefficients that are used in the real-time processing loop and the real-time processing loop itself. The real-time loop consists of simple multiplications and additions, which are simple to perform in real-time, and the coefficient computation, which requires complicated transcendental functions, trigonometric functions, and other operations which can not be performed effectively in real-time. Fortunately, the coefficients are static during run-time and can be pre-computed before real-time processing takes place. These coefficients can be specifically computed for each audio device in which digital signal processing method 100 is to be used. Specifically, when digital signal processing method 100 is used in a mobile audio device configured for use in vehicles, these coefficients may be computed separately for each vehicle the audio device may be used in to obtain optimum performance and to account for unique acoustic properties in each vehicle such as speaker placement, passenger compartment design, and background noise.

For example, a particular listening environment may produce such anomalous audio responses such as those from standing waves. Such standing waves often occur, for example, in small listening environments such as an automobile. The length of an automobile, for example, is around 400 cycles long. In such an environment, some standing waves are set up at this frequency and some below. Standing waves present an amplified signal at their frequency which may present an annoying acoustic signal. Vehicles of the same size, shape, and of the same characteristics, such as cars of the same model, may present the same anomalies due to their similar size, shape, structural make-up, speaker placement, speaker quality, and speaker size. The frequency and amount of adjustment performed, in a further embodiment, may be configured in advance and stored for use in graphic equalizer 107 to reduce anomalous responses for future presentation in the listening environment.

The “working tables” shown in the previous section all consist of pre-computed values that are stored in memory and retrieved as needed. This saves a tremendous amount of computation at run-time and allows digital signal processing method 100 to run on low-cost digital signal processing chips. It should be noted that the algorithm as detailed in this section is written in block form. The program described above is simply a specific software embodiment of digital signal processing method 100, and is not intended to limit the present invention in any way. This software embodiment may be programmed upon a computer chip for use in an audio device such as, without limitation, a radio, MP3 player, game station, cell phone, television, computer, the speakers of the present invention, or public address system. This software embodiment has the effect of taking an audio signal as input, and outputting that audio signal in a modified form.

While various embodiments of the present invention have been described above, it should be understood that they have been presented by way of example only, and not of limitation. Likewise, the various diagrams may depict an example architectural or other configuration for the invention, which is done to aid in understanding the features and functionality that can be included in the invention. The invention is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present invention. Also, a multitude of different constituent module names other than those depicted herein can be applied to the various partitions. Additionally, with regard to flow diagrams, operational descriptions and method embodiments, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the invention may be described or embodied in the singular, the plural is contemplated to be within the scope thereof unless limitation to the singular is explicitly stated.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or embodied as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. An audio system comprising:
a speaker comprising one or more mismatched speaker components which are operably coupled to each other such that the components, together, have a low frequency response; and
a signal processor operably coupled to the one or more mismatched speaker components, the signal processor configured to process an input signal and to drive the speaker using the processed signal such that the speaker has a higher frequency response than the low frequency response.

2. The audio system of claim 1, wherein the magnet is a rare earth magnet.

3. The audio system of claim 1, wherein the mismatched components comprise a voice coil and a magnet, wherein the voice coil is oversized in relation to a size of a magnet of the speaker.

4. The audio system of claim 3, wherein the signal processor is further configured to prevent the larger voice coil from overdriving the magnet.

5. The audio system of claim 1, wherein the cone comprises organic fibers.

6. The audio system of claim 5, wherein the cone is dampened which contributes to the low frequency response.

7. The audio system of claim 1 wherein the signal processor further comprises:
a first filter configured to filter a signal to obtain a generally flat power spectral density;
a gain controller configured to alter a dynamic range of the signal by reducing the ratio between a signal's peak level and a signal's average level;
a second filter configured to convert the signal to a full frequency response;
an equalizer configured to equalize the signal; and
an output configured to output the signal to the speaker.

8. The audio system of claim 7, wherein the equalizer comprises a 10 band parametric equalizer.

9. The audio system of claim 7, wherein the first and the second filter each comprise a high and low shelving filter combination set.

10. The audio system of claim 7, further comprising a pre-input high pass filter configured to filter a signal received by the audio system.

11. The audio system of claim 7, further comprising a leaky integrator configured to gain adjust the signal by computing a loudness level of the signal.

12. A method to process a signal to compensate for a speaker comprising mismatched components, the method comprising:
receiving a signal;
filtering a signal to obtain a generally flat power spectral density;
altering a dynamic range of the signal by reducing the ratio between a signal's peak level and a signal's average level;
converting the signal to a full frequency response;
equalizing the signal; and
outputting the signal to a speaker with one or more mismatched components.

13. The method of claim 12, further comprising receiving a selection of an audio play back device; and calibrating the equalizer based on the selection.

14. The method of claim 12, further comprising:
filtering the signal to limit low frequencies; and
gain adjusting the signal by computing a loudness level of the signal.

15. The method of claim 14, wherein gain adjusting further comprises increasing a gain of the signal based on the loudness level.

16. The method of claim 14, wherein gain adjusting further comprises decreasing a gain of the signal based on the loudness level.

17. The method of claim 12, further comprising configuring a signal processor to compensate for a low frequency response produced by mismatched components of a speaker.

18. The method of claim 12, further comprising gain adjusting the signal, after filtering the signal, to modify the gain level of the signal.

19. The method of claim 12, further comprising loudness adjusting to compensate for loudness variations.

20. The method of claim 12, further comprising compressing the signal after filtering a signal to obtain a generally flat power spectral density.

21. The method of claim 12, further comprising compressing the signal after equalizing.

22. A computer readable medium comprising instructions executable by a processor for performing a method to process a signal to compensate for a speaker comprising mismatched components, the method comprising:
receiving a signal;
filtering a signal to obtain a generally flat power spectral density;
altering a dynamic range of the signal by reducing the ratio between a signal's peak level and a signal's average level;
converting the signal to a full frequency response;
equalizing the signal; and
outputting the signal to a speaker with one or more mismatched components.
